(19) United States
(12) Patent Application Publication
(10) Pub. No.: US 2002/0083858 A1
(43) Pub. Date: Jul. 4, 2002

(54) Spontaneous pattern formation of functional materials

(76) Inventors: Alan G. MacDiarmid, Drexel Hill, PA (US); Dirk Hohnholz, Philadelphia, PA (US); Hidenori Okuzaki, Yamanashi (JP)

Correspondence Address: LAHIVE & COCKFIELD, 28 STATE STREET, BOSTON, MA, 02109, US

(21) Appl. No.: 09/858,154

(22) Filed: May 15, 2001

Related U.S. Application Data
(60) Provisional application No. 60/204,091, filed on May 15, 2000.
(60) Provisional application No. 60/207,392, filed on May 26, 2000.
(60) Provisional application No. 60/252,502, filed on Nov. 22, 2000.
(60) Provisional application No. 60/252,507, filed on Nov. 22, 2000.

(51) Int. Cl. B41F 1/54; B41L 47/56; B41L 39/00; B41F 33/00

(52) U.S. Cl. 101/484

(57) ABSTRACT

A method of forming a pattern of a functional material on a substrate is disclosed. In accordance with the method, a first pattern of a first material is applied to the substrate and a second functional material is applied to the substrate and the first material. The first material, the second functional material, and the substrate interact to spontaneously form a second pattern of the second functional material on the substrate. The invention is directed to methods for spontaneous pattern formation of functional materials on substrates, and devices produced according to the methods of the invention. In particular, the methods of the invention provide a simple, inexpensive method for patterning a functional material on a substrate, with broad applicability to numerous devices.

### CROSS REFERENCE TO RELATED APPLICATIONS

This application claims the benefit of U.S. Provisional Application No. 60/204,091, filed May 15, 2000, U.S. Provisional Application No. 60/207,392, filed May 26, 2000, U.S. Provisional Application No. 60/252,502, filed Nov. 22, 2000, and U.S. Provisional Application No. 60/252,507, filed Nov. 22, 2000, the disclosures of all of which applications are hereby incorporated herein by reference in their entireties.

### GOVERNMENT SUPPORT

This invention was supported in part by funds from the U.S. Government (Office of Naval Research Grant No. ONR-N00014-92-J-1369) and the U.S. Government may therefore have certain rights in the invention.

### BACKGROUND OF THE INVENTION

Patterning of functional materials by direct printing techniques has been used in a number of applications. For example, R. H. Friend et al. (Science, 290, 2123-2126, (2000)) used patterning to provide a low-cost alternative for the fabrication of integrated circuits, and more specifically, to advance cost-effective thin film transistor technology. In particular, Friend et al were able to improve resolution of the inkjet printing of an aqueous solution of a conductive polymer ink onto a hydrophobic photoresist, deposited photolithographically onto a substrate, by inkjet printing the conductive polymer ink directly into a pattern of channels plasma etched into the photoresist. Resolution of the printed lines of polymer was improved by taking advantage of the reduction of surface free energy between the hydrophilic ink and the hydrophobic photoresist.

Alternatively, patterning of functional materials has been used in applications that require mixing prevention barriers. For example, U.S. Pat. Nos. 6,177,214, 6,042,974, 5,817,441, 5,94,577, 5,898,208, and 6,207,329, assigned to Cannon Kabushiki Kaisha, describe the use of such barriers in liquid crystal displays (LCDs) and color filters. Kobayashi et al. (Synthetic Metals 111-112, 125-128 (2000)) describe the formation of banks between each pixel on a glass substrate that facilitated the patterning of electroluminescent layers on a thin film transistor substrate using ink jet printing in order to synthesize a RGB multicolor light-emitting polymer display. In addition, U.S. Pat. Nos. 6,004,617 and 5,985,356 describe the application of patterned barriers to prevent mixing of reactants in adjacent regions in a parallel synthesis strategy for the combinatorial synthesis of materials. In all of these applications, a second functional material is directly printed, e.g., by ink-jet printing, within the regions defined by the barriers. U.S. Pat. No. 6,080,606 describes electrophotographic patterning techniques in the preparation of amorphous silicon thin film transistors (TFTs). In particular, a toner pattern is electrophotographically printed onto a substrate, and the patterned substrate is coated with an electrically conductive material such that both the substrate and the toner lines are coated with the material. The coated toner lines must then be removed to leave a pattern of the electrically conductive material on the substrate. Thus, the ultimate pattern of the electrically conductive material is generated only after the coated toner lines are removed.

Accordingly, a simple, inexpensive method for patterning a functional material on a substrate, useful for a number of applications, is needed. Additionally, such a method should not be dependent on resolution of the lines of the pattern, nor require the directed application, e.g., printing, of the pattern of the functional material onto the substrate.

### BRIEF DESCRIPTION OF THE DRAWINGS

FIG. 1 illustrates a schematic of an apparatus used to measure the surface resistivity of a substrate in accordance with the invention.

FIG. 2 illustrates a schematic of a coating apparatus used in accordance with the invention.

FIG. 3 illustrates 10 interdigitated patterns printed using a printer of the type set forth in Table 1.

FIG. 4 illustrates two of the interdigitated patterns of FIG. 3 further identifying the areas used for measurement of surface resistivity and resistance.

FIG. 5 shows the dependence of the measured surface resistivity on the number of coatings using composition BE1 as the second material.

FIG. 6 illustrates the first conductive pattern layer prepared using Line Patterning (LP) on a transparent substrate, e.g., an overhead transparency, for use in the preparation of a solar cell.

FIG. 7 illustrates the pattern printed on top of the circuit element of FIG. 6 in the preparation a solar cell.

FIG. 8 illustrates the pattern printed on top of the circuit element of FIG. 7 in the preparation of a solar cell.

FIG. 9 illustrates the resulting layered structure of the solar cell made from the pattern layers of FIGS. 6-8.

FIG. 10 illustrates a multi-layered chessboard pattern device, comprised of an interdigitated pattern, a coating of PEDOT-PSS, followed by a second interdigitated pattern printed orthogonally to the first. An additional coating of PEDOT-PSS was applied and the resulting pattern is illustrated. FIG. 11 illustrates the pattern of FIG. 10, after the removal of the toner lines.

FIG. 12 illustrates a surface structure that is prepared utilizing either the difference in height of printing or the difference in height of coated/non-coated areas as obtained by the Line Patterning process of the invention, where the height is dependent on the coating material and the number of coatings.

FIG. 13 illustrates a surface structure similar to that in FIG. 12, that is used to seal or align mechanical devices.

FIG. 14 illustrates the side view of the device of FIG. 13.

FIG. 15 illustrates a conductive pattern that is formed on a flexible substrate using the Line Patterning technique for forming a speaker/buzzer apparatus.

FIG. 16 illustrates the side view of the circuit element of FIG. 15.

FIG. 17 illustrates conductive patterns that are formed on a flexible substrate in the preparation of an electrostatic actuator using the Line Patterning technique of the invention.

FIG. 18 shows the side view of the circuit element of FIG. 17 during operation.

FIG. 19 illustrates conductive patterns that are formed on a flexible substrate in the preparation of a conducting polymer fuse using the Line Patterning technique of the invention.

FIG. 20 illustrates conductive patterns formed on a flexible substrate in the preparation of a variable resistor using the Line Patterning technique of the invention.

FIG. 21 illustrates the circuit element of FIG. 20 during operation.

FIG. 22 illustrates conductive patterns that are formed on a substrate in the preparation of circuitry in a commercial dual-in-line IC socket using the Line Patterning technique of the invention.

FIG. 23 illustrates conductive patterns that are formed on a substrate in the preparation of a hybrid assembly as a component for printed circuit boards using the Line Patterning technique of the invention.

FIG. 24 illustrates the assembly schematic of commercially available Y-shaped pins that are crimped to the contact pads of a hybrid assembly.

FIG. 25 illustrates conductive patterns that are formed on a substrate in the preparation of an OTP ROM element using the Line Patterning technique of the invention.

FIG. 26 illustrates a conductive pattern that is formed on the circuit element illustrated in FIG. 25 in the preparation of an OTP ROM element.

FIG. 27 illustrates the side view of the circuit element of FIG. 26.

FIG. 28 illustrates conductive patterns that are formed on a substrate in the preparation of a coil using the Line Patterning technique of the invention. FIG. 29 illustrates conductive patterns formed on a substrate in the preparation of resistors using the Line Patterning technique of the invention.

FIG. 30 shows the dependence of the resistance on the length of the resistor prepared using Line Patterning in accordance with the invention.

FIG. 31 illustrates conductive patterns formed on a substrate in the preparation of capacitors using the Line Patterning technique of the invention, using composition BE1 as the second material.

FIG. 32 illustrates conductive patterns formed on a substrate in the preparation of a Field Effect Transistor (FET)-like circuit element using the Line Patterning technique of the invention.

FIG. 33 illustrates the connection schematic used to determine the circuit element characteristics of the FET-like circuit element of FIG. 32.

FIG. 34 shows the typical I/U characteristics observed for the FET-like circuit element of FIG. 32.

FIG. 35 illustrates the operational circuit element of the embodiment of FIG. 32.

FIG. 36 illustrates a comparative embodiment of an operational FET-like circuit element made using the Line Patterning technique of the invention.

### SUMMARY OF THE INVENTION

The invention is directed to methods for spontaneous pattern formation of functional materials on substrates, and devices produced according to the methods of the invention. In particular, the methods of the invention provide a simple, inexpensive method for patterning a functional material on a substrate, with broad applicability to numerous devices. Additionally, the methods of the invention are not dependent on resolution of the lines of the pattern, nor do the methods of the invention require the directed application, e.g., printing, of the pattern of the functional material onto the substrate.

Thus, in one embodiment, the invention is a method of forming a pattern of a functional material on a substrate. In accordance with the method, a first pattern of a first material is applied to the substrate and a second functional material is applied to the substrate and the first material. The first material, the second functional material, and the substrate interact to spontaneously form a second pattern of the second functional material on the substrate.

Another embodiment of the invention is a method of forming a pattern of a functional material on a substrate using non-contact printing. A first pattern is applied to a substrate by non-contact printing and a second functional material is then applied to the substrate and the first material. The first material, the second functional material, and the substrate interact to spontaneously form a second pattern of the second functional material on the substrate.

In yet another embodiment, the invention is a method of forming a pattern of a functional material on a substrate using non-contact printing. In this embodiment, the first material and second functional material are selected to have a sufficient difference in at least one property of hydrophobicity and hydrophilicity relative to one another such that the first material, the second functional material, and the substrate interact to spontaneously form a second pattern of the second functional material on the substrate.

In one aspect, the invention is directed to a method of forming an electrical circuit element using the methods described above. Thus, a first pattern of a first material is applied to the substrate and a second functional material is applied to the substrate and the first material. The first material, the second functional material, and the substrate interact to spontaneously form a second pattern of the second functional material on the substrate, thereby form an electrical circuit element.

In a related aspect, the invention is directed to an electrical circuit element prepared by the methods described above. In a particular embodiment, a first pattern of a first material is applied to the substrate and a second functional material is applied to the substrate and the first material. The first material, the second functional material, and the substrate interact to spontaneously form a second pattern of the second material on the substrate, thereby forming an electrical circuit element.

In another aspect, the invention is an electrical circuit element. The circuit element comprises: a substrate; a first pattern of an insulating material applied to the substrate; and a second electrically conducting material applied to the substrate and the first material, wherein the insulating material, electrically conducting material, and the substrate interact to spontaneously form a second pattern of the electrically conducting material on the substrate, when the electrically conducting material is applied to the substrate having the first pattern of the insulating material applied thereon.

In a related aspect, another embodiment of the invention is an electronic device comprising a combination of circuit elements. Such a device is prepared using the methods of the invention described above and in more detail below. In accordance with this embodiment, the electronic devices comprises:

a) a first circuit element comprising

i) a first substrate;

ii) a first pattern of an insulating material applied to the substrate and

iii) a second pattern of an electrically conducting material applied to the substrate and the first material, wherein the insulating material, electrically conducting material, and the substrate interact to spontaneously form a second pattern of the electrically conducting material on the substrate when the electrically conducting material is applied to the substrate having the first pattern of the insulating material applied thereon;

b) a second circuit element comprising

i) a second substrate;

ii) a third pattern of an insulating material applied to the second substrate and

iii) a fourth pattern of an electrically conducting material applied to the second substrate and the third material, wherein the insulating material, electrically conducting material, and the second substrate interact to spontaneously form a fourth pattern of the electrically conducting material on the substrate when the electrically conducting material is applied to the substrate having the third pattern of the insulating material applied thereon; and

C) an electrical connection between the first and second circuit elements.

In a specific device embodiment, the invention is a Radio Frequency (RF) tag. The RF tag comprises a pattern of a nonconductive first material and a coating of an electrically conductive second material disposed over the substrate and the first material, wherein the first material, the second material and the substrate interact to spontaneously form a second pattern of the electrically conductive material on the substrate.

An additional embodiment of the invention is a mechanical device comprising a combination of mechanical components. Such a device is prepared using the methods of the invention described above and in more detail below. In accordance with this embodiment, the mechanical devices comprises:

a) a first component comprising

i) a first substrate;

ii) a first pattern of first material applied to the first substrate and iii) a second pattern of material applied to the first substrate and the first material, wherein the second pattern of the second material is spontaneously formed by the interaction of the first material, the second material and the first substrate; and

b) a second component comprising

i) a second substrate;

ii) a third pattern of a third material applied to the second substrate and

iii) a fourth pattern of fourth material applied to the second substrate and the third material, wherein the fourth pattern of the fourth material is spontaneously formed by the interaction of the third material, the fourth material and the substrate; and wherein the first and second components are oriented in a such a way that the second and fourth patterns oppose each other, and are selected from the group consisting of identical patterns, inverse patterns, and any mechanically useful combinations.

In another aspect, the invention is directed to electrical circuit elements, electronic devices, mechanical devices and other articles of manufacture which are prepared by the methods of the invention summarized hereinabove and described in more detail hereinbelow.

### DETAILED DESCRIPTION OF THE INVENTION

The invention is directed to methods for spontaneous pattern formation of functional materials on substrates, and devices produced according to the methods of the invention. In particular, the methods of the invention provide a simple, inexpensive method for patterning a functional material on a substrate, with broad applicability to numerous devices. Additionally, the methods of the invention are not dependent on resolution of the lines of the pattern, nor do the methods of the invention require the directed application, e.g., printing, of the pattern of the functional material onto the substrate.

Thus, in one aspect, the invention is directed to methods of forming a pattern of a functional material on a substrate. In accordance with the method, a first pattern of a first material is applied to the substrate and a second functional material is applied to the substrate and the first material. The first material, the second functional material, and the substrate interact to spontaneously form a second pattern of the second functional material on the substrate. In another aspect, the invention is directed to devices prepared using the methods of the invention.

I. Definitions

Before further description of the invention, certain terms employed in the specification, examples, and appended claims are, for convenience, collected here.

The term “pattern” as used herein refers to an array, arrangement or configuration of lines and/or shapes, areas and/or regions.

The terms “patterning” and “line patterning” are used interchangeably herein, and refer to the use of a predesigned first pattern of a first material to generate a second pattern of a second material on a substrate. In other words, the first pattern serves as a template for generation of the second pattern. The interaction among and between the first material, the second material, and the substrate results in spontaneous formation of a second pattern of the second material. Thus, the second pattern can be predetermined to the extent that its generation, although spontaneous, is based on the first pattern as a template.

The term “material” as used herein refers to any material, e.g., element, mixture of elements, compound, mixture of compounds, etc. that can be applied to a given substrate, and is limited only by the availability of application techniques. In general, the materials used in accordance with the invention can comprise electronic, organic, inorganic, or organo-metallic materials in monomeric, oligomeric, or polymeric forms in solution, dispersion, or gaseous state.

The term “functional”, e.g., as in “second functional material” or “functionally active material”, refers to materials that have at least one function or utility that is non-decorative, although functional materials as used herein may have a decorative function or utility in addition to a non-decorative function or utility. The functional utility of the material may be inherent or may be engineered. In certain embodiments of the invention, the functionality of a material can be imparted to the material as a result of chemical or physical manipulations, and/or interactions among and between the substrate and one or more other materials.

The term “substrate” as used herein refers to a platform, support, or any material to which the patterns and materials described herein can be applied. Substrates that are useful in the invention can be categorized by surface properties such as hydrophilicity, solubility in specific solvents, surface roughness, transparency, flexibility, etc. Accordingly, the term includes glass, e.g., glass film, metal, e.g., metal film or foil, plastic, wood, fabric, paper, quartz, crystals, stone, and ceramics. Additionally, the term “substrate” is intended to encompass substrates as defined above, to which at least one material has already been applied (e.g., coated substrates). A transparency film, a subset of the general class of plastic substrates, is a class name for a variety of different materials. Most common are the polyester films (type I or type II, available from 3M) and polyehtyleneterephtalate (PET, available from Nashua, Corporation). Nashua XF-20 transparencies are expected to be PET material, and 3M Transparencies, e.g. 3M PP2500 are expected to contain a special coating. Furthermore, the term “substrate” is also intended to include custom-doped substrates that may be useful for semi-conducting applications.

The terms “applying” and “application of a material” as used herein refer to the act or process by which a material is placed onto a substrate, either in the form of a pattern, or as a material to be spontaneously patterned in accordance with the invention.

The terms “interact” and “interactions” as used herein refer to the relative rates at which two or more materials physically and/or chemically react such that the materials are attracted to or repulsed from one another. Examples of such interactions are those that reduce surface free energy of the materials involved, and include hydrophobic/hydrophilic, ionic(e.g., coulombic attraction/ repulsion, ion-dipole, charge-transfer), solvent wettablility, chemical bonding, Van der Waals, general mechanical adhesion, hydrogen bonding, penetration, and magnetic interactions.

The term “general mechanical adhesion” as used herein refers to Lock-and-Key interactions or physical interactions, in which adhesion is the result of a supplementary pattern that the adhesive forms with a non-uniform surface, e.g., a “tongue and groove” interaction whereby a tongued surface of a first material interlocks and hence adheres to the grooved surface of a second material.

The term “penetration” as used herein refers to chemical interactions in which a first “guest” material chemically penetrates, e.g., dissolves, the surface of a second “host” material, such that the first and second materials are bound together by a fused intermediate layer, e.g., after drying.

The term “multi-layered pattern” as used herein refers to two or more patterns of two or more respective materials, arranged such that a distinct layer is formed for each material, whereby the layers may be of different materials and/or have patterns that overlay.

The term “overlay” as used herein refers to the act of patterning a material over a preexisting pattern in any orientation, such that the patterns are in contact in at least one point; e.g., directly over the preexisting pattern (exact overlay of patterns), orthogonal to the preexisting pattern, askew in relation to the preexisting pattern, or substantially overlaying the preexisting pattern.

The term “spontaneously” as used herein refers to an action that is self-acting, or developing without apparent external influence, force, cause, or treatment, and without temporal limitations.

The term “substantially uniform” as in “applied substantially uniformly” or “applied in a substantially uniform manner” refers to the application of a material in a non-pattern-specific or unpatterned manner that results in an undirected, homogeneous application of the material to substantially the entire substrate, or to substantially the entire portion of a substrate. For example, substantially uniform application of a material to a substrate in accordance with the invention is distinguished from directed application (e.g., printing) of a material to a substrate. The term “information carrying material” as used herein refers to a material that either contains information that can be extracted, or that conveys or is capable of conveying information, e.g., electronic or digital information.

The term “engineered functionality” as in “material having an engineering functionality” refers to a material that is made functional through chemical or physical modification and/or spatial configuration (e.g., patterning) as distinguished from materials that are inherently functional.

The term “removing the first pattern” as used herein refers to removing the first material, by any means, such that it becomes functionally insignificant in relation to the second material. For example, following spontaneous pattern formation of the second pattern of the second material, the first pattern of the first material may be removed to such an extent that the measurable height of the first pattern of the first material that remains is not greater than 1 micron, and the second pattern of the second material is substantially unaltered.

The term “cleaning by mechanical action” as used herein refers to using any physical action to directly remove a pattern of a material. Examples include cleaning using a cloth, a brush, a gas jet, cutting, scraping and/or abrasion.

The term “non-contact printing” as used herein refers to printing techniques in which the formation of a pattern does not require contact of a physical object containing the pattern with a receiving substrate that the pattern is being printed upon, and does not require substrate preparation, e.g., coating of the substrate. The term “formation” is defined as the point of inception of the pattern. Examples of non-contact printing techniques include electrophotographic printing, e.g., laser printing, xerographic printing, inkjet printing, and solid ink printing.

The term “offset printing” as used herein refers to a printing technique in which the ink is transferred to a pattern, then transferred to a blanket, and finally printed on the desired substrate.

The term “photolithographic printing” as used herein refers to a printing method for generating patterns by coating with a photoresist, exposure to a light pattern, development of the photoresist, and removal of the undeveloped part of photoresist.

The term “silk-screen printing” as used herein refers to a printing technique that generates patterns using a fabric screen, through which ink is pressed onto the substrate, and a stencil. The stencil is positioned to allow the ink to be transferred to the substrate through the part of the stencil that has been cut out in the form of the desired pattern.

The term “stamping” as used herein refers to a printing technique that generates patterns by application of a stamp, carved with the desired pattern and to which ink has been applied, to the substrate. The ink adheres to the surface of the substrate, leaving a pattern of ink, determined by the carving of the stamp, on the substrate.

The term “etching” as used herein refers to a printing technique that generates patterns by the selective removal of material from the surface of a substrate by means of the chemical or physical action of an etchant (or etching agent). Etching alters the surface properties of the substrate by at least one of, chemically activating the surface, changing the surface roughness, or selective removal.

The term “hand-drawing” as used herein refers to a printing technique that generates patterns by application of a manually or computer guided pen to apply an ink on the substrate, or otherwise mechanically changing the surface of the substrate.

The term “electrophotographic printing” as used herein refers to a printing technique that generates patterns in which dry ink, e.g., toner, adheres to electrically charged areas of a photosensitive drum, which is then transferred to a substrate. Ultimately, the dry ink is fixed with heat onto the substrate. The areas of the transfer drum become charged through exposure to a light source.

The term “laser printing” as used herein refers to an electrophotographic printing technique, in which a laser writes on a “drum” that becomes electrically charged in areas of laser light contact. The drum is then exposed to dry ink, e.g., toner, that is electrostatically transferred to the drum and later to a substrate.

The term “xerographic printing” as used herein refers to an electrophotographic printing technique that generates a pattern from a pre-existing physical pattern, e.g., drawings on paper or three-dimensional objects, in which dry ink, e.g., toner, adheres to electrically charged areas of a photosensitive drum resulting from exposure to light source, which is then transferred to a substrate. Ultimately, the dry ink is fixed with heat onto the substrate. The image that is generated is a duplication or modification, e.g., enlargement or reduction in size, of the original pre-existing pattern.

The term “solid ink printing” as used herein refers to a printing technique that generates patterns by application of a solid ink that is temporarily softened to a molten state, sprayed onto a transfer drum, and then transferred to the substrate where it solidifies. Solid inks typically consist of a host, e.g. a wax, and a guest, e.g. the color dye.

The term “line resolution” as used herein refers to the definition of a line created by a printing technique. More specifically, the line resolution may be described by the measured distance depicting the statistical variation of the flight direction of droplets and their spreading during application on the substrate.

The term “inverse” as used herein refers to a description of a pattern, made in reference to its negative image, as is commonly used in a photographic sense. The term “negative” is used synonymously.

The term “electrically active material” as used herein refers to one or a combination of materials that interact or are capable of interacting with electricity, and is intended to include materials that not only interact with electricity, but also interact with electricity associated with light, e.g., dyes, with chemicals, e.g., for sensing other materials, with temperature, with biological materials (e.g., living organisms), radiation, or magnetism.

The term “electrically conductive material” as used herein refers to an electrically active material that has the particular property of conducting electricity, and is intended to include metals, e.g., gold, silver, copper, iron, alloys, and electrically conductive polymers, e.g., poly-3,4-ethylenedioxythiophene-polystyrene sulfonate (PEDOT-PSS).

The term “electrically conductive polymer” as used herein refers to a polymer, such as PEDOT-PSS, polyaniline, or polypyrrole, that can be applied to a substrate and conducts electricity.

The term “conductance” as used herein refers to the ability of the material to allow the transport of electricity from one position of the material to another position. A greater conductance corresponds to greater charge transport.

The term “nonconductive ink” as used herein refers to ink that has the property of very low conductance, such that the ink substantially lacks the ability to conduct electricity.

The term “adhesive modification through chemical alteration” as used herein refers to the process of chemically modifying the state or existence of a compound in order to decrease the adhesive properties of the compound in relation to another material or substrate.

The term “circuit element” as used herein refers to patterned materials of the invention that function as circuit components well-known to those who are skilled in the art including but not limited to an inductor, a resistor, a capacitor, an Inductor-Capacitor (LC) resonator, a switch, a filter, a transistor, a Schottky junction, a p-n junction, and a sensor. The circuit element can comprise part of an electronic device or can constitute an electronic device in and of itself.

The term “electronic device” as used herein refers to a circuit element, or a combination of circuit elements, that possesses the ability to perform designed functions when supplied with power.

The term “sensor” as used herein refers to a circuit element that responds, in a definable manner, e.g., with an electrical impulse or a color change, to changes in conditions, including pressure, light, electrical current, energy, or chemical or biological species to which it is exposed.

The term “filter” as used herein refers to a circuit element that filters specific frequencies of alternating current.

The terms “insulator” and “insulating material” as used herein refer to a material or a characteristic of a material, respectively, that provides containment of electrical activity within defined, or insulated, regions. Materials are classified as insulators or insulating material because of their low conductance. A toner ink is one example of an insulator.

The term “mechanical device” as used herein refers to a device in which pattern formation is used to impart to a device its physical presence or structural function. Examples of mechanical devices according to the invention include micro-fluidic channels, seals, snap-in fittings, keypads, and touchpads.

The term “component” as used herein refers to a substrate comprising a pattern of a material applied to the substrate prepared by applying a first pattern of a first material to a substrate, followed by the application of a second material to the substrate and the first material. The first material, the second material, and the substrate interact to spontaneously form a second pattern of the second material on the substrate, forming a building block or component of a mechanical device.

The term “mechanically useful combinations” as used herein refers to two or more components that combine to provide a mechanical device that is engineered for a specific purpose.

The term “snap-in fittings” as used herein refers to an interconnection characterized by the existence of a physical relationship between two inversely related patterns such that the patterns can be positioned to provide a physical interconnection, or fitting, between the patterns. The patterns compliment each other, such that the interconnection is made when one pattern “snaps” into the other.

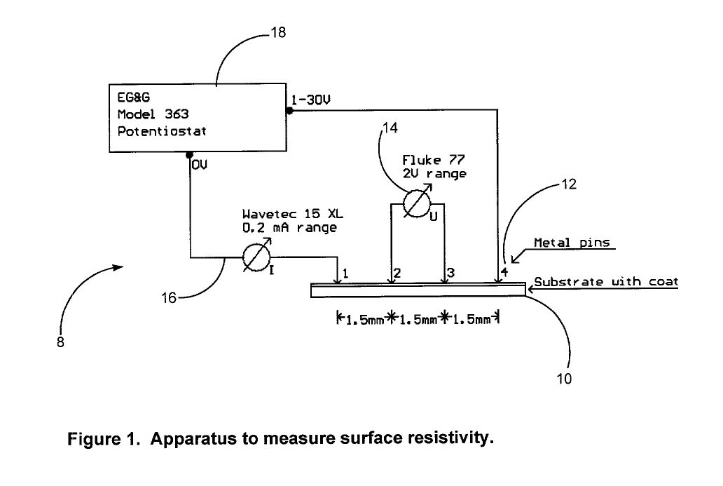

The term “surface resistivity” as used herein refers to a measured value determined using a resistivity measuring device 8 as shown schematically in FIG. 1. The resistivity measuring device 8 includes a potentiostat 18 electrically coupled to an ammeter 16 and a metal pin 12. Another voltmeter 14 measures the potential between two points on a substrate 10. Values of I and U were determined by adjusting the current, I, between 0.001 mA and 0.1 mA and reading the respective values of the potential, U. The surface resistivity was calculated using the equation: R [Ω/square]=4.5 U/I (L. J. Van der Pauw et al, Philips Res. Reports, 9, (1958)).

Several terms that are used herein to describe compositions utilized in the Examples below are described and abbreviated for convenience as follows:

Baytron P:

Baytron P, U4071, LOT# K0051, Bayer Corporation, Electronic Materials, 100 Bayer Road, Pittsburgh, Pa. 15205-9741. This chemical shall be referred to herein as “Baytron P.”

Composition BE1:

10 mL of Baytron P and 0.5 mL ethyleneglycol were added into a 20 mL vial with a screw cap. The vial was closed and manually shaken for 30 seconds. This composition shall be referred to herein as “Composition BE1” or “BE1”.

Composition ED1:

10 mL ethyleneglycol and 1 drop (approximately 15 mg) dodecylbenzenesulfonic acid (DBSA) were added to a 20 mL vial with a screw cap. The vial was closed and manually shaken for 30 seconds. This composition shall be referred to herein as “Composition ED1” or “ED1”.

Composition BED1:

10 mL Baytron P and 2 mL Composition ED1 were added to a 20 mL vial with screw cap. The vial was closed and manually shaken for 30 seconds. The composition was used immediately after preparation. This composition shall be referred to herein as “Composition BED1” or “BED1”.

Nashua XF-20:

Nashua XF-20 transparency for plain paper or dry toner copiers with opaque stripe. Nashua Corporation, 57 Daniel Webster Hwy S, Merrimack, N.H. 03054. Substrates of this type shall be referred to herein as “Nashua XF-20”.

Weyerhaeuser Paper:

Weyerhaeuser Laser Copy paper, white 8.5″×11″, item 1180, Weyerhaeuser Company, P.O. Box 9777, Federal Way, Wash. 98063-9777, USA. Substrates of this type shall be referred to herein as “Weyerhaeuser paper”.

LaserJet 5000N:

Hewlett Packard LaserJet 5000N, Hewlett Packard Corporation, USA. HP print cartridge, HP LaserJets 1100/a & 3200, product C4129X, R 94-9001-410. This printer and toner shall be referred to herein as “LaserJet 5000N”.

Tektronix Phaser 350:

Tektronix Phaser 350, solid ink printer, Xerox Corporation, previously Tektronix Corporation, USA. ColorStix Ink, Black, Phaser 340/350/360 Printers, Part No. 016-1307-01. This printer and ink shall be referred to herein as “Tektronix Phaser 350”.

Tektronix Paper: Tektronix Printer Paper 24# bond, A-Size, 8.5″×11″, re-order No. 016-1368-00. This substrate shall be referred to herein as “Tektronix paper”.

II. Methods of the Invention

The invention is directed to a method of forming a functional material on a substrate. A first pattern of a first material is applied to the substrate and a second functional material is applied to the substrate and the first material. The first material, the second material, and the substrate interact to spontaneously form a second pattern of the second functional material on the substrate.

In certain embodiments, the first material is applied first followed by application of the second functional material. In other embodiments, the first material and the second functional material are applied substantially simultaneously. In yet other embodiments, the second functional material is applied first followed by application of the second functional material.

For example, in a specific embodiment, the second functional material is applied substantially uniformly to a substrate. Then, the first material is patterned onto the substrate coated with the second functional material. The first material and the second functional material interact to spontaneously form a pattern of the second functional material resulting from attraction or from repulsion to the first pattern.

In another specific embodiment, the second functional material is applied as an aqueous solution to the substrate. The first material is then patterned onto the coated substrate and breaks the aqueous surface tension of the wet coating of the second functional material, wherein the first material, the second material, and the substrate interact to thereby form an inverse pattern of the second functional material with respect to the first pattern.

In still another specific example, a soft, e.g., wax-like, or volatile second functional material is applied to a substrate. The first material is patterned onto the coated substrate in such a way that it mechanically deposits through the soft or volatile second material on the substrate (e.g., in the case where the second functional material is wax-like, the first material is patterned as a hot composition, such that it melts through the second material to the substrate), wherein the first material, the second material, and the substrate interact to thereby pattern the second material.

In general, a first pattern of a first material is applied to a substrate. The manner of application of the first pattern is not limited. Techniques that may be used to apply the first material include non-contact printing, photolithographic printing, offset printing, silk-screen printing, stamping, etching, hand-drawing, and any combination thereof. Non-contact printing is intended to include all printing techniques in which the formation of a pattern does not require contact of a physical object containing the pattern with a receiving substrate that the pattern is being printed upon, and lacking the requirement of substrate preparation, e.g., coating of the substrate. The term “formation” is further classified to define the point of inception of the pattern.

The type of first material is limited only by application techniques available for its deposition onto the substrate in the form of a pattern. In other words, if a material can be applied to a substrate, then it is suitable for use in the invention. The first material may be any compound or composition, e.g., combination of compounds, e.g., suspension or solution, such that the material can be applied by any known technique, including those techniques enumerated above. In general, the first material can comprise electronic, organic, inorganic, or organo-metallic materials in monomeric, oligomeric, or polymeric forms in solution, dispersion, or gaseous state. In certain embodiments, the first material may be electrically non-conductive, for example, a nonconductive ink, or even more specifically, a toner ink. In other embodiments, the first material may be a polyimide.

In accordance with the invention, the substrate is any material that can serve as a platform or support for one or materials to be applied. In certain embodiments, the substrate to which the first pattern is applied includes glass, metal, plastic, wood, fabric, paper, quartz, crystal, stone, and ceramic. Furthermore, the term substrate is intended to additionally encompass substrates as defined above, in which at least one material has already been applied. In particular embodiments, the substrate is flexible. Moreover, in specific embodiments, the flexible substrate is a flexible plastic substrate, e.g., in an electrostatic actuator (Example 21). Alternatively, in specific embodiments, the substrate is a conductive material, e.g., a metal. In an additional embodiment, the substrate is a custom-doped material.

In one embodiment of the invention, the first material is polypyrrole that is selectively deposited as polypyrrole thin films on a hydrophobic glass substrate and on a hydrophilic glass substrate. In another embodiment of the invention, the first material is polyaniline that is selectively deposited as polyaniline thin films on a hydrophobic glass substrate and a hydrophilic glass substrate. In certain embodiments of the invention, the hydrophobic glass substrate is coated with a mono-layer of C₁₈H₃₇(SiCl₃). In certain embodiments, the hydrophilic glass substrate is treated with H₂SO₄ and H₂O₂. In specific embodiments, the films deposited on the hydrophilic or hydrophobic surfaces had the same order of magnitude thickness, but their conductivities varied because of the differences in continuity of the respective films. In particular embodiments, the deposition of a thin film on the hydrophobic substrate resulted in a more continuous film and therefore a film with a greater conductivity.

A second functional material is applied to the substrate, or a portion thereof, and the first material, such that the first material, the second material, and the substrate interact to spontaneously form a second pattern of the second material on the substrate. In general, the second material is limited only by application techniques available for its deposition onto the substrate. As with the first material, the second material may be any compound or composition, e.g., combination of compounds, e.g., suspension or solution, such that the material can be applied by any technique available for deposition onto a substrate, including those enumerated above. In general, the second functional material can comprise electronic, organic, inorganic, or organo-metallic materials in monomeric, oligomeric, or polymeric forms in solution, dispersion, or gaseous state.

In certain embodiments, the second material is applied substantially uniformly to the substrate containing the first pattern, or to a portion of the substrate containing the first pattern, resulting in an undirected, homogeneous application of the second material to the substrate. Techniques for the substantially uniform application of the second material include rolling the second material onto the substrate, spraying the second material onto the substrate, melting the second material onto the substrate, dipping the substrate into the second material, or exposing the substrate to gasses or vapors of the second material. In a specific embodiment of the invention, substantially uniform application of the second material is accomplished by rolling the second material onto the substrate. Additional methods of application of the second material are described in U.S. Pat. Nos. 6,004,617 and 5,985,356. In a further embodiment, a third material is substantially uniformly applied to the substrate containing the second material by rolling the third material onto the substrate, spraying the third material onto the substrate, melting the third material onto the substrate, dipping the substrate into the third material, or exposing the substrate to gasses or vapors of the third material, such that the second and third materials combine and/or react to produce a functionally active fourth material.

In another embodiment, the first or the second material may be a biopolymer or an oligomer thereof. Moreover, in certain embodiments, the functionally active material may be the first material, the second material, the substrate, or any combination thereof.

A number of embodiments of the invention involve the application of an electrically active second material. Electrically active materials include one or a combination of materials that interact or are capable of interacting with electricity, and is intended to include materials that not only interact with electricity, but also interact with electricity associated with light, e.g., dyes, with chemicals, e.g., for sensing other materials, with temperature, with biological materials (e.g., living organisms), radiation, or magnetism. In certain embodiments, the electrically active material is an electrically conductive material including polymeric materials, metallic dispersions, metallic solutions, a sol gel of indium tin oxide, non-polymeric materials, and derivatives thereof. In particular, the electrically conductive material comprises an electrically conductive polymer such as, for example, polypyrroles, polythiophenes, polyanilines, poly-phenylenevinylenes, polyacetylenes, derivatives thereof, and combinations thereof. In certain embodiments of the invention, the second material is applied as an aqueous mixture of an electrically conductive polymer. For example, in a specific embodiment of the invention, poly-3,4-ethylenedioxythiophene-polystyrene sulfonate (PEDOT-PSS) is used as the electrically conductive polymer. Advantageously, PEDOT-PSS is applied to the substrate as an aqueous mixture. Alternatively, the second material comprises an electrically conductive non-polymeric material. Electrically conductive non-polymeric materials include, for example, phthalocyanines, porphyrins, anthracenes, fullerenes, triphenylamines, stilbenes, and derivatives thereof.

Conversely, the second material can comprise an electrically non-conductive material. For example, in certain embodiments, the second material comprises an information carrying material that either contains information that can be extracted, or that conveys or is capable of conveying information, e.g., electronic or digital information. In particular embodiments, the resulting functionality may be engineered to provide patterns for specific applications.

In certain embodiments, a substrate is used that has a conductance that is lower than that of the second material. In other embodiments, the first material has a conductance that is lower than that of the second material.

The spontaneous formation of the second pattern is the result of the interactions among and between the first material, the substrate, and the second material. In general, the patterning of the second material is based on the rate of the general interactions of attraction and repulsion. Therefore, the patterning of the second material may be accomplished in one of two ways: attraction of the second material to the first material and repulsion from the substrate; or repulsion of the second material from the first material and attraction to the substrate. Accordingly, the former interactions result in a pattern of the second material that directly overlays the first pattern. The latter interactions result in a pattern of the second material that is the inverse, or negative, of the first pattern.

Interactions of attraction and repulsion include, for example, interactions such as hydrophobic/hydrophilic, ionic, e.g., coulombic attraction/ repulsion, ion-dipole, charge-transfer, solvent wettablility, chemical bonding, Van der Waals, general mechanical adhesion, hydrogen bonding, penetration, and magnetic interactions. In addition, more than one type of interaction between the first material, second material, and the substrate may be involved in the spontaneous pattern formation of the second material.

In a specific embodiment of the invention, the interaction among the first material, the second material, and the substrate to spontaneously form a second pattern of the second material on the substrate is primarily hydrophobic/hydrophilic in nature.

As previously noted, the first material can be applied to the substrate by just about any method or technique. In certain embodiments of the invention, the first material is applied to the substrate by non-contact printing. In more specific embodiments of the invention non-contact printing includes electrophotographic printing and solid ink printing. Electrophotographic printing embodiments include laser printing and xerographic printing. In certain embodiments, non-contact printing the first pattern results in a first material that has a line resolution of at least about 10 μm.

In an additional specific embodiment toner ink is used as a convenient and commercially available first material in electrophotographic printing. Electrophotographically printing toner ink onto a substrate provides patterns that can be used for different embodiments of the invention, including, for example: a containment barrier for aqueous compositions, because of the hydrophobic nature of the toner ink; an electrical insulator, because of the dielectric properties of the toner ink; and a structural support, because of the mechanical resistance and cohesive nature of the toner ink. Another embodiment of the invention is the application of an additional pattern of an additional material to the substrate, thereby forming a multi-layered pattern of materials on the substrate. The additional materials of the multi-layered pattern may be the same or different than the first and second materials such that the additional pattern of additional material is the same as the first pattern. Furthermore, this pattern may be overlaid, directly over an existing pattern or may be applied in any other orientation. In a specific embodiment, the additional pattern is applied orthogonally to the first pattern. For example, as described in Example 13 in which the additional material (toner ink) is the same as the first material, the toner ink is applied to a transparency electrophotographically to form a chessboard pattern, and then an aqueous solution of poly-3,4-ethylenedioxythiophene-polystyrene sulfonate (PEDOT-PSS) is applied to the chessboard pattern. A second application of the first pattern of the first material is applied over the existing bilayer pattern orthogonal to the first application of the first pattern, creating a third layer.

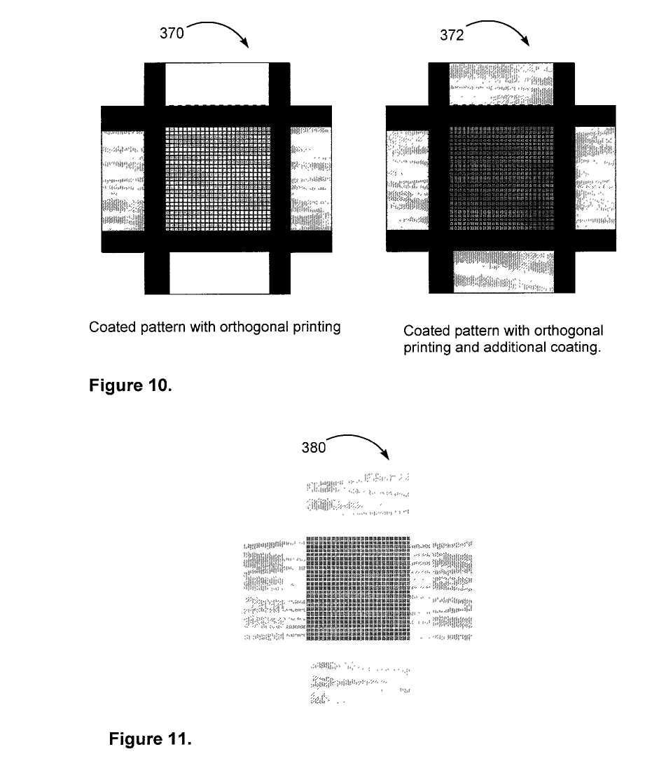

Alternatively, in another embodiment, the additional materials of the multi-layered pattern may be the same or different than the first and second materials such that the additional pattern of additional material is the same as the second pattern. Furthermore, this pattern may be overlaid, exactly over an existing pattern or may be applied in any other orientation. Example 13 further describes the application of a fourth material, identical to the second material and patterned in the same manner as the second material. The resulting multi-layered pattern, shown in FIG. 10, provides thick films of a conducting polymer, PEDOT-PSS. Those skilled in the art will readily appreciate that this methodology of preparing thick films can be extended to other electrically conductive materials. In another embodiment of the invention, the additional materials of the multi-layered pattern may be the same or different than the first and second materials, such that the additional pattern of additional material is different from the first and second pattern.

In a related embodiment, the invention provides a convenient route for the preparation of multi-layer composite materials, whereby an additional pattern of additional material is applied to overlay the first and second patterns, creating a multi-layer composite material. In a specific aspect of this embodiment of the invention, the first and second materials are semi-conducting materials, such that the application of these semi-conducting materials creates semi-conducting junctions within the multi-layered composite material produced. In another specific embodiment of the invention, a semi-transparent conductive composite material is prepared by laser printing a pattern of toner ink lines on a substrate, applying a suspension of PEDOT-PSS, and depositing an additional coating of doped polypyrrole (prepared by reacting pyrrole, FeCl₃*6H₂O, and Fe(TOS)₃ suspended or dissolved in a solvent, e.g., water), and removing the first pattern in the manner described in Example 10.

Depending on the specific substrate and/or application, an additional processing step for preparing the patterned devices according to the invention may be desired. For example, such an additional processing may be needed to remove small amounts of electrically conductive bridging material, unintentionally connecting two insulated regions of conducting material. In addition, it may be desirable to remove the pattern to provide a transparent device.

Thus, in another embodiment, the method of the invention can further comprise removal of a pattern of material, for example the first pattern of the first material. This embodiment of the invention is referred to as the “3-Step” process of line patterning as distinguished from the “2-Step” process of line patterning, and is described in Example 2 in comparison to the “2-Step” process.

In general, a pattern of material, for example the first pattern of the first material, can be removed by any means, such that the pattern of material becomes functionally insignificant in relation to another material, e.g., the second material, on the substrate.

Techniques for removal of a pattern, for example, the first pattern of the first material, include ultrasonic treatment with a solvent, cleaning with a solvent, cleaning by mechanical action, adhesive modification through chemical alteration, evaporation, and melting. The selection of solvents to be used for pattern removal are dependent upon the composition of the patterning material and include water, glycol, glycerol, dimethylformamide, dimethylsulfoxide, toluene, tetrahydrofuran, chloroform, hexanes, and gasoline. In certain embodiments, the solvent is an organic solvent. In other embodiments where the pattern to be removed comprises lines of toner ink, toluene is advantageously used to remove the pattern of toner ink lines.

As noted above, it may be necessary to remove small amounts of electrically conductive material that unintentionally bridge the first and second materials, thereby connecting two or more otherwise insulated regions of conducting material. The 3-Step process of the invention can be used to alleviate this problem.

Two embodiments of the 3-step process for removing unintentional connections are described in Example 6: the application of a 400 Volt direct current (DC) potential between the unintentionally connected areas; and the removal of the first pattern and thereby concurrently removing the unintentional bridges disposed over the first pattern.

Alternatively, a third method of removing unintentional connections includes isolating the region of the unintentional bridge by measurement of the surface resistivity using device 8, shown schematically in FIG. 1, and using a knife to physically remove the unintentionally bridging material.

In general, the “3-Step” process results in the preparation of devices with patterns containing more reliable insulating lines between the contiguous regions of conductive coating on the substrate than those obtained with the“2-Step” process. The percent of devices obtained that are faulty because of such unintentional bridges is dependent upon the interaction properties among and between the first material, second material, and the substrate with respect to each other. Thus, a decrease in the number of faulty devices can be achieved by consideration of the following sources of error: 1) the entirely manual coating process, 2) the coarseness of the substrate, 3) inhomogeneity within the stream of air, 4) experimental error associated with the measurement equipment, and/or 5) the composition of the second material.

The removal of the patterned material, for example, the pattern of the first material, is advantageous in many other applications and/or devices, including: capacitor preparation, as described below; display screens, in which the removal of the black toner lines is desired for better image resolution, improved quality of the optical appearance of the device, and restoration of transparency; preparation of touch pads; reduction of height of the first material above the substrate to enable subsequent processing steps; generation of wells; and exposure of the substrate surface to allow further deposition on the substrate.

Examples 4 and 7 below describe the preparation of a homologous chessboard pattern using a “3-Step” process embodiment of the invention. In contrast, Examples 3 and 5 describe the preparation of homologous and heterogeneous chessboard patterns, respectively, using the 2-Step process embodiment of the invention.

In certain embodiments of the invention, the first material is advantageously applied using non-contact printing techniques. Non-contact printing is intended to include all printing techniques in which the formation of a pattern does not require contact of a physical object containing the pattern with a receiving substrate that the pattern is being printed upon, and also does not require substrate preparation, e.g., coating of the substrate. The term “formation” is defined as the point of inception of the pattern. Thus, non-contact printing techniques include electrophotographic printing and solid ink printing. In advantageous embodiments of the invention, electrophotographic printing includes laser printing and xerographic printing. In certain embodiments, non-contact printing the first pattern results in a pattern of the first material that has a line resolution of at least about 10 μm.

In another aspect, the invention is directed to a method of preparing an electrical circuit element using the methods of the invention. Thus, a first pattern of a first material is applied to the substrate and is followed by the application of a second material to the substrate and the first material. The first material, the second material, and the substrate interact to spontaneously form a second pattern of the second material on the substrate, thereby creating an electrical circuit element. In an advantageous embodiment of this aspect of the invention, the second pattern that is spontaneously generated is the inverse of the first pattern. That is, the second pattern is spontaneously formed due to a repulsion of the second material from the first pattern of the first material and an attraction of the second material to the substrate. Therefore, in accordance with this aspect of the invention, a number of electrical circuit elements can be prepared, including inductors, resistors, capacitors, Inductor-Capacitor (LC) resonators, switches, filters, transistors, Schottky junctions, p-n junctions, and sensors.

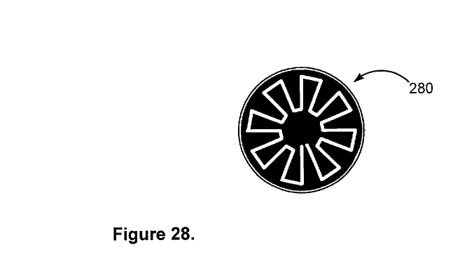

In a specific electrical circuit element embodiment of the invention, an inductor is prepared in accordance with the invention such that the second pattern comprises a serpentine pattern or a spiral pattern. In a specific embodiment of the inductor, a coil, shown in FIG. 28, is composed of a conductive pattern prepared by patterning an aqueous suspension of PEDOT-PSS, using toner ink patterns electrophotographically deposited by a laser printer onto a substrate in the manner described in Example 27. Those skilled in the art will appreciate that the wheel pattern of FIG. 28 can be rotated around its middle axis in a static magnetic field to induce current into the coil. Additionally, exposure to an alternating magnetic field can produce a similar effect as rotation in this static magnetic field. Applications of such a device include a converter of rounds/minute into voltage, e.g., a speedometer, a power supply for electronic circuitry, and an ultra-lightweight motor, e.g., containing motor coils comprising patterns comparable to those described above.

In another specific embodiment, a resistor-like element, with a well defined resistance, shown in FIG. 29, comprises a conductive pattern prepared by patterning an aqueous suspension of PEDOT-PSS, using toner ink patterns electrophotographically deposited by a laser printer onto a substrate in the manner described in Example 28. The resistor-like element is defined by the length, width, and height of the second pattern and the conductivity of the second material.

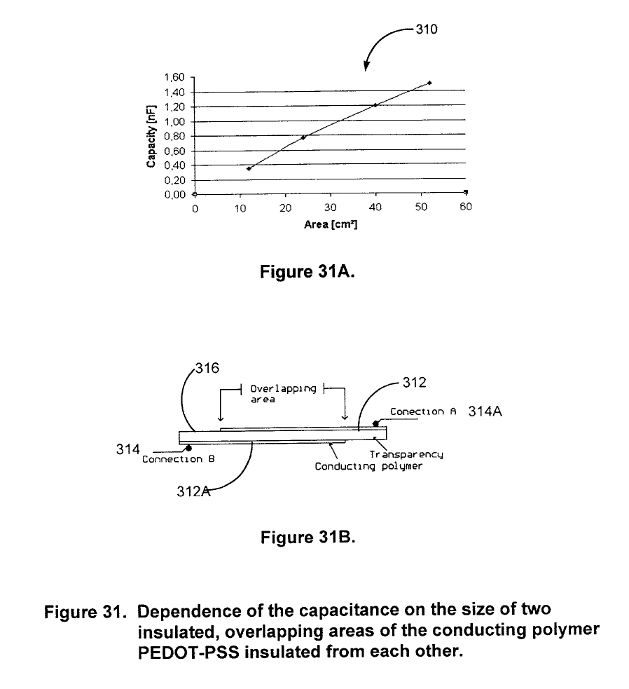

Another embodiment is a capacitor-like element, with a well defined capacitance, shown in FIG. 31, that comprises two conductive patterns prepared by patterning an aqueous suspension of PEDOT-PSS, using toner ink patterns electrophotographically deposited by a laser printer onto opposite sides of a transparency substrate, aligned in the manner depicted in FIG. 31 and described in Example 29. In an alternative embodiment, a capacitor-like element can be prepared by patterning an aqueous suspension of PEDOT-PSS in the image of two adjacent but electrically insulated areas on side of a substrate, using toner ink patterns electrophotographically deposited by a laser printer on the same side of a single transparency substrate. The toner ink is then removed, providing a capacitor containing air as the dielectric material of the capacitor, whose capacitance is a function of the distance and the length of the adjacent areas of the PEDOT-PSS lines. Those skilled in the art will appreciate that in this embodiment, the air dielectric resulting from the removal of the toner ink can be reloaded with a variety of materials possessing a range of dielectric properties.

In another embodiment, the electrical circuit element further comprises a second circuit element, wherein the second circuit element is formed by non-contact printing a third pattern of a third material on a second substrate, followed by the application of a fourth material to the second substrate and the third material. A fourth pattern is formed spontaneously as a result of the interactions between the third material, the fourth material, and the second substrate. In one embodiment, the second material and fourth material on the first and the second substrates comprise an electrically conductive material. In this embodiment, the pattern of the first substrate and the pattern of the second substrate are opposed to each other so as to form a switch in which the electrically conductive material on each substrate is separated by the respective heights on the substrates of the first material and the third material. Thus when at least one of the substrates is depressed, the electrically conductive materials are physically put into electrical contact with each other. In certain embodiments, the first and third materials are the same.

One embodiment of an electrical circuit element of the invention is a Resistor-Capacitor (RC) filter. A specific embodiment of the RC filter comprises a first pattern of electrically conductive material connected to electrical ground, a second pattern of electrically conductive material connected to an input signal at one end of the second pattern and to an output at another end of the second pattern, and at least one capacitor electrically connected between the first and second patterns to form an RC filter.

Another embodiment of an electrical circuit element of the invention is a transistor, in which the electrically active material comprises a semi-conducting polymer deposited on the substrate as at least one of a source, a drain, and a connection between the source and drain. In a specific embodiment, the semi-conducting polymer material is applied as a control layer forming a gate disposed over the electrically conductive polymer material connecting the source and the drain and separated therefrom by an insulator. In advantageous embodiments, the semi-conducting polymer material can be a conducting polymer, a phthalocyanine, a porphyrin, an anthracene, a fullerene, a triphenylamine, a stilbene, or derivatives thereof.

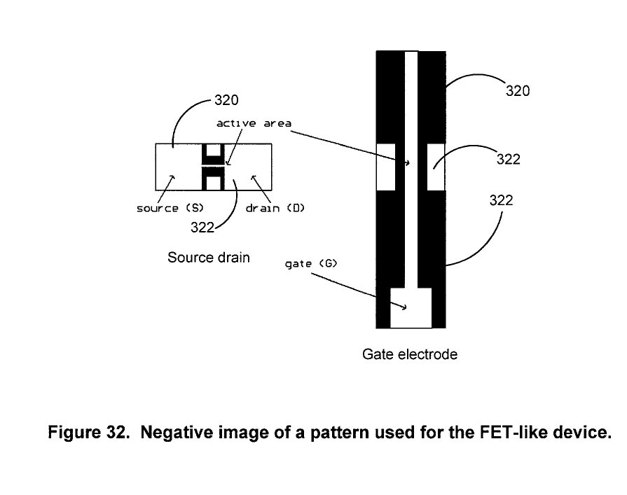

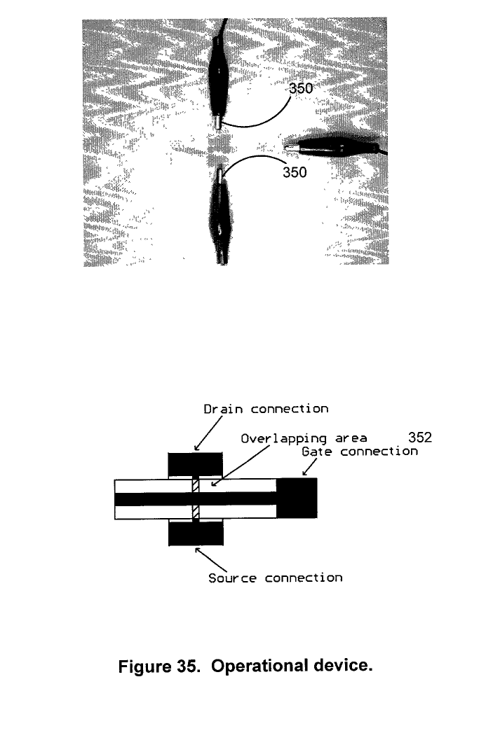

In another embodiment, an FET-like device, shown in FIG. 35, comprises two conductive patterns, as shown in FIG. 32, prepared by patterning an aqueous suspension of PEDOT-PSS, using toner ink patterns electrophotographically deposited by a laser printer onto a transparency substrate, aligned and insulated from each other in the manner described in Example 30.

Those skilled in the art will appreciate that similar “FET”-like devices can be fabricated by using the following:

Different substrates, e.g., films, e.g., transparency films, fabric, paper, ceramics, glass, custom-doped substrates, and the like;

Different organic semiconducting materials, e.g., polyaniline, polypyrrole, polythiophene, pentacene, fullerene and their derivatives, and inorganic semiconductors, e.g., silicon, both in doped and non-doped forms, or composites of all of the above with semiconducting or conducting materials, and the like;

Different insulating materials, e.g., polyethylene, siliconnitride, siliconoxide, air, inert gasses, inert liquids;

Other materials as “insulating” layer, e.g., liquid crystal materials, photo-responsive, radiation-sensitive, thermo-responsive or chemically responsive materials for applications as sensors;

Different spacers, e.g., fibers, mesh, fabric, air, printed lines; and

Organic or inorganic conductors, e.g., metal.

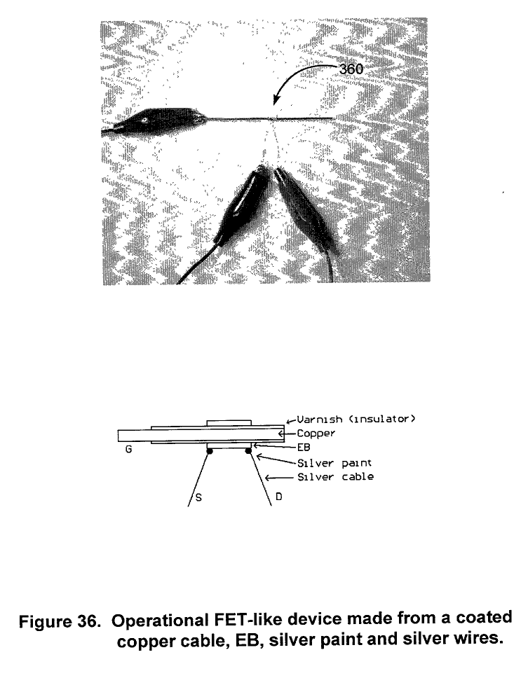

For a comparative analysis, an additional FET-like device, as shown in FIG. 36, was fabricated in the manner described in Example 31. The device was connected and characterised in a similar manner to that described in Example 30, resulting in characteristics highly similar to those shown in FIG. 34 for Example 30.

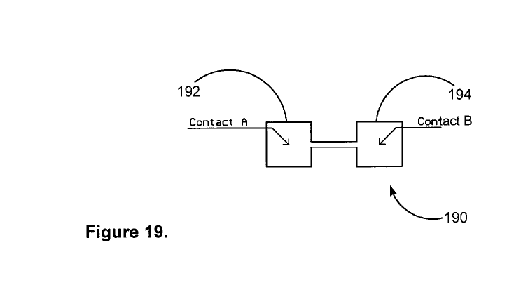

Another embodiment of a circuit element in accordance with the invention is a conductor polymer fuse, or sensor, shown in FIG. 19, comprising a conductive pattern that is prepared by patterning an aqueous suspension of PEDOT-PSS, using toner ink patterns electrophotographically deposited by a laser printer onto a substrate in the manner described in Example 22. Those skilled in the art will appreciate that the behavior of this device was dependent on the geometry and type of material used to construct the device. Applications of such a device include electric stress sensors, e.g., for use in “classic” electronic assemblies, that detect the location of the circuitry breakdown, and use as fuses.

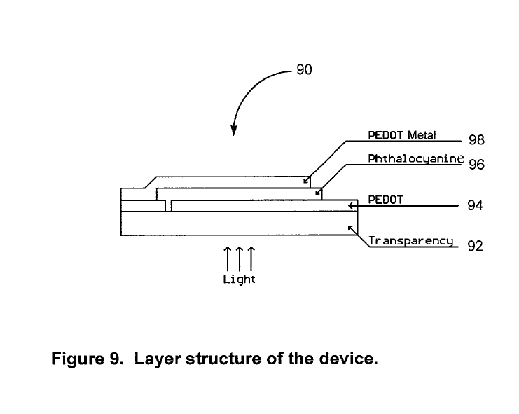

In another embodiment of a circuit element of the invention, a solar cell is prepared by patterning an aqueous suspension of PEDOT-PSS, using toner ink patterns electrophotographically deposited by a laser printer onto a transparent substrate, and ultimately coated with an additional layer of a charge separating compound, as described in Example 17. FIG. 9 shows the resulting layered structure of the solar cell of this example. Those skilled in the art will appreciate that solar cells with higher efficiency can be obtained by stacking these films or devices, and will further appreciate that the device depicted in FIG. 9 can be used as a background of a display. Applications of the solar cell include light level sensors in cameras or shadow sensitive elements, e.g., for “touch-screens.”

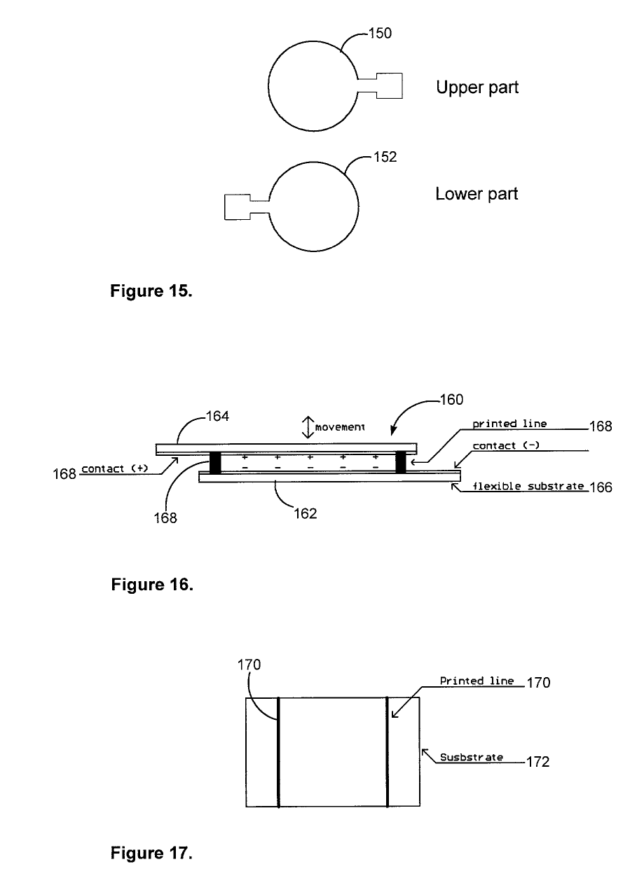

Another specific embodiment of the invention is a speaker, or buzzer, shown in FIG. 16, that comprises two separate parts. As shown in FIG. 15, these two parts are prepared by patterning an aqueous suspension of PEDOT-PSS, using toner ink patterns electrophotographically deposited by a laser printer onto a flexible substrate, and aligning the two parts such that the printed circles overlap in the manner described in Example 20. Those skilled in the art will appreciate that the shape or size and material of the device can be used to cause resonance at specific frequency ranges. Also, when the resonance is strongly induced, a contact of both charged areas can occur resulting in an immediate, distinguishable, change in current flow into the device, that can be utilized to detect the specific frequency. Applications of such a device include speakers and frequency detectors in which the device appears to “deactivate” at specific frequencies determined by the device dimensions.

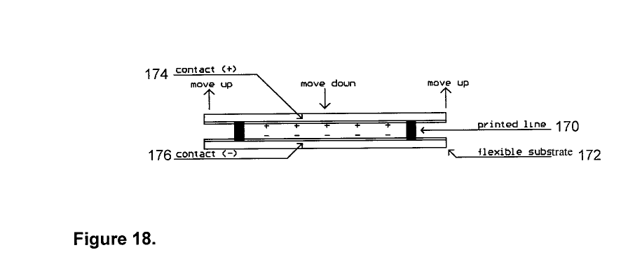

Yet another embodiment of the invention is an electrostatic actuator, shown in FIG. 18, that comprises two identical conductive patterns, as shown in FIG. 17. These patterns are prepared by patterning an aqueous suspension of PEDOT-PSS, using toner ink patterns electrophotographically deposited by a laser printer onto a flexible substrate. The two patterns are aligned in the manner described in Example 21. In certain embodiments, the first or second material can be electrically active. In a specific embodiment, the electrically active material can be used to guide or propagate light. Those skilled in the art will appreciate that such a device can be stacked to obtain a more developed lift or lowering, or that an insulator can be cast on or placed between the conductive sides to prevent sparks. Applications of such a device include an actuator for mechanical watches, mini-robots, e.g., actuators or movable parts, stirring or mixing in microfluidic applications, channeling the flow of reagents or test samples, microelectromechanical systems (MEMS), and light-beam adjustment/focusing for use in, e.g., an optical switch.

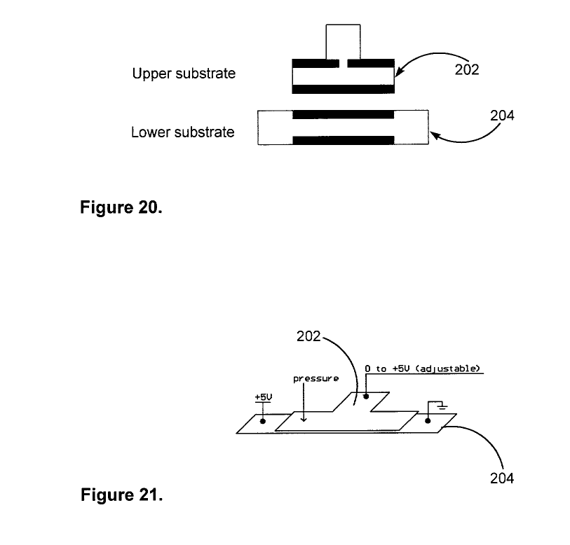

Another embodiment of a circuit element in accordance with the invention is a variable resistor, shown in FIG. 21, which comprises two conductive patterns, as shown in FIG. 20. The patterns are prepared by patterning an aqueous suspension of PEDOT-PSS, using toner ink patterns electrophotographically deposited by a laser printer onto a substrate, and aligning the two patterns in the manner described in Example 23. Those skilled in the art will appreciate that the device can be designed as a circle to measure the position of the pressure within a turn instead of a longitudinal direction. The device can also be of almost any shape, and used to follow complex movements of the lever. Additionally, the device can be bent into a variety of three-dimensional shapes to fit into a desired apparatus. Applications of such a device include: a variable resistor, a variable capacitor (trimmer or padder), a position sensor in complex machinery, and a position sensor for electronic games, e.g., checkerboard games.

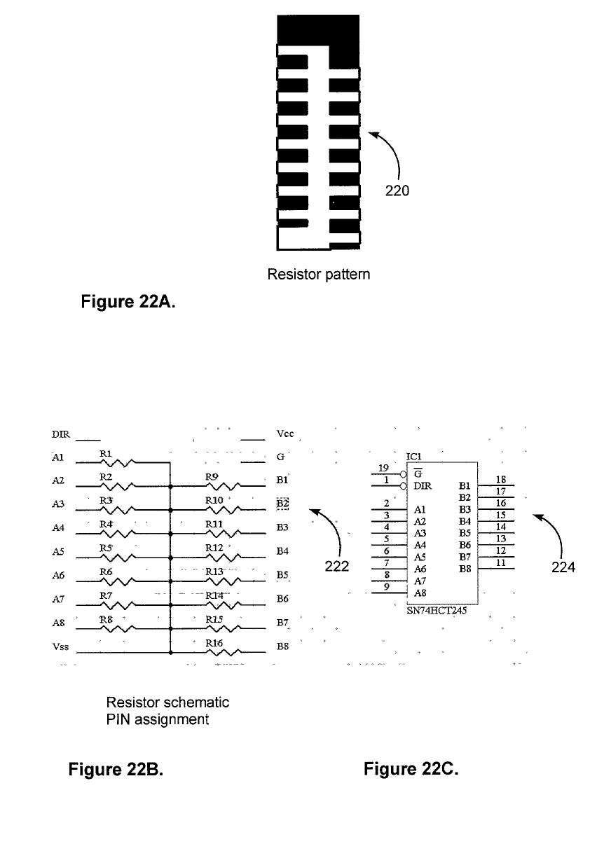

Still another embodiment of the invention is a custom designed integrated circuit (IC) socket, shown in FIG. 22, that comprises a conductive pattern, as shown in FIG. 22. The pattern is prepared by patterning an aqueous suspension of PEDOT-PSS, using an ink pattern that is applied electrophotographically by a laser printer or physically by stamping onto the plastic surface of a commercial dual-in-line 20-IC socket in the manner described in Example 24. Those skilled in the art will appreciate that such circuitry can also be built onto the integrated circuit or onto the printed circuit board. In addition, by creating two adjacent but insulated areas of conductive material, a capacitor can be created that can be connected between the power supply pins of the integrated circuit. Applications of such circuitry include improved electronic components that may be printed directly onto a substrate

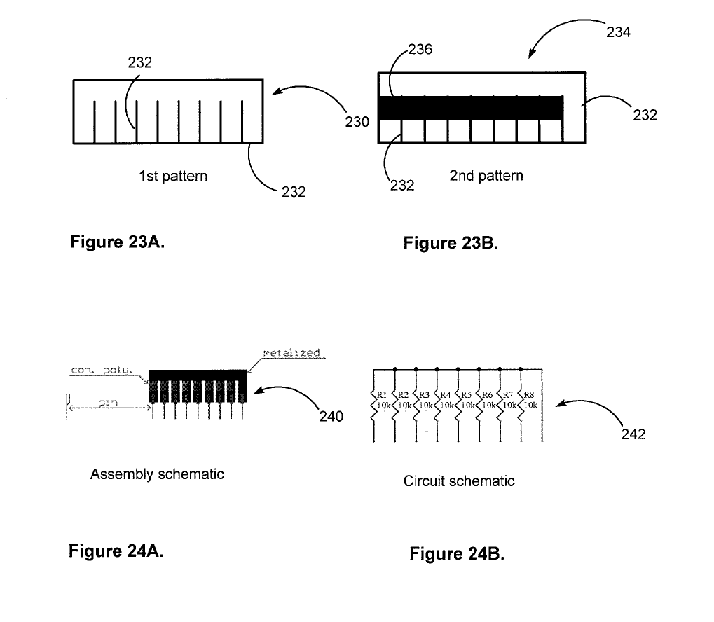

In an additional embodiment of the invention, an hybrid assembly as a component for a circuit board, shown in FIG. 24, comprises two conductive patterns shown in FIG. 23. The patterns are prepared by patterning an aqueous suspension of PEDOT-PSS, using toner ink patterns electrophotographically deposited by a laser printer onto a substrate. Commercially available Y-shaped pins are crimped to the contact pads of a metallized surface, in the manner described in Example 25. Those skilled in the art will appreciate that other electronic or mechanical components can be prepared in this “hybrid assembly” manner, and that low resistance connection lines can be achieved by using thick conducting polymer coatings instead of metallization. Applications of this technique include low cost hybrid electronic assemblies for printed circuit boards and integrated circuits with low weight and low profile.

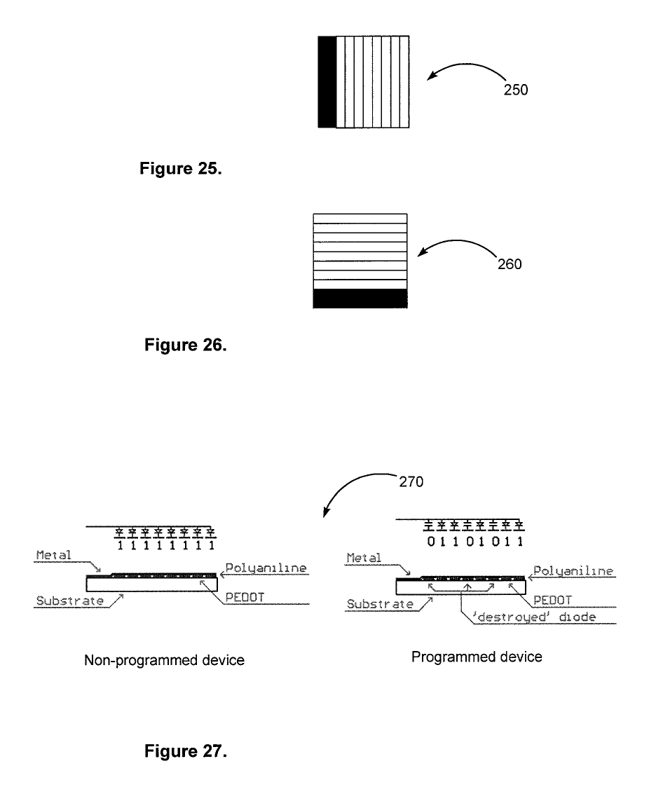

One additional embodiment of the invention is a 64 bit (8×8) one-time programmable read only memory (OTP ROM) element, shown in FIG. 27, that comprises the two conductive patterns shown in FIGS. 25 and 26. The patterns are prepared by patterning an aqueous suspension of PEDOT-PSS, using toner ink patterns electrophotographically deposited by a laser printer onto a substrate, and sequentially coated with an emeraldine salt and a metal, in the manner described in Example 26. Those skilled in the art will appreciate that the device can be pre-programmed during construction and can be used to make memory for intelligent tags or memory for a variety of electronic circuitry, e.g., microprocessors and programmable read only memories (PROM).

In another aspect, the invention is directed to electronic devices that comprise one or any combination of two or more circuit elements electrically interconnected, including those described above, and that possess the ability to perform designated functions when supplied with power. In certain embodiments, the electrical connection may be provided by a fastener, such as a three dimensional interconnect, e.g., a rivet, a grommet, a metal staple, a coated metal staple, a metal wire, a snap, or a coated metal wire.

One embodiment of an electronic device prepared according to the methods of the invention is a Radio Frequency (RF) tag. In a specific embodiment, an RF tag comprises a pattern of a nonconductive first material on a substrate and a coating of an electrically conductive second material disposed over the substrate and the first material, such that a second pattern of the second material is spontaneously formed on the substrate due to the interactions of the first material, the second material, and the substrate, to thereby form an Inductor-Capacitor (LC) resonator on the substrate. In further specific embodiments, the first material and the substrate are selected to have sufficient differences in at least one of hydrophobicity and hydrophilicity relative to the electrically conductive second material. In certain other embodiments, the electrically conductive material and the pattern of the first material together may form a capacitor and an inductor on the same side of a substrate or a capacitor and an inductor on respective sides of a substrate that are connected to one another through the substrate.

Several other embodiments of the electronic devices of the invention are described in Table A1.

TABLE A1
Embodiments of electronic devices as described by the invention.

| Product | Description |
|---|---|
| RF-theft-protection tag on paper | LC resonator circuit on paper. Resonance ˜6 MHz. Replacement of |
| | tags as currently used with less expensive substrate and production |
| | method. |
| Keypads/touchpads | Keypads/touchpads made from two coated substrates, separated by |
| | the height of the printed lines. |
| Pocket calculator/remote control | Hybrid of keypad, display and mounted single chip processor. |
| Tokens (coins) | A conductive pattern is prepared on each “coin” (e.g., a target-like |
| | structure). When the “coin” is inserted into reader, its pattern is |
| | electronically read and enables the mechanism. |
| Electrically readable key-card | Cardboard key-card, that is inserted into a reader and allows access |
| | through doors. |
| Antennas | Flat antennas to be mounted in radio or cell phone. |
| Circuit board hybrids (Radio, toys | Hybrids of circuit board and mounted standard components. |
| etc.) | |
| Sensor tags | Tags that sense environmental conditions and provide information |
| | on the exposure of a product. |
| Electrophoresis electrodes | 3D electrodes for applications in electrophoresis with micro-fluids. |
| Sensor pads for medical equipment | Adhesive pads to be applied in electro-cardiography or other |
| | medical monitoring applications. |
| Smart windows | Windows responding to light. The window keeps the light level in |
| | the room constant, independent of the light level outside. |
| Anti-static cabinets | EMI shielded cabinets for sensitive electronic equipment. Lead in |
| | and lead out terminals are not coated due to line patterning and thus |
| | are not insulated from the housing. |
| Touch screens | Grids of conductive material responsive to touch, utilizing |
| | electrostatic effects. |
| Electronic seals (fraud protection, | When the electronic seal is broken, a visible or electronically |
| product integrity) | readable irreversibly reacts. |
| Greeting cards, interactive paper | Combination of a display or other output device and switches. |
| | When the switch is closed, the output device is activated, e.g., |
| | touching the greeting card at a certain area of multiple choice, |
| | flashes the word “Winner”. |
| Electronic components | Components for hybrid electronic circuits. Flat resistors, capacitors, |
| | etc., to be mounted in PCB assemblies. |
| PCBs with embedded components | Multi-layer circuit board assembly with embedded components like |
| | resistors and capacitors. |
| Alarm/damage tracking system | Sensors responding to mechanical destruction to track source and |
| components | location of faults, e.g., grids of impact sensors. |
| Solar cells | Low cost flexible solar cells. |
| Instant lottery | Customer encodes a conductive pad by scratching connections |
| | away, each representing a choice, e.g., select 3 numbers out of 20. |
| | The customer inserts the card into a slot. A reader device “rolls |
| | dice” and determines if the customer has chosen a “lucky” |
| | combination and receives a bonus, e.g, of $2. |
| Personal monitoring equipment | Set of sensors determining the current state of the person wearing it. |
| | Sensors are sensitive to humidity, temperature, heart pulses, |
| | exposure to infectious disease, etc. |
| Voting system | Individual cards with names of candidates. Voter places a card into |
| | a slot, where the machine identifies candidates, counts, and marks |
| | card. Voter puts the card into an envelope and throws it into |
| | collection flask. If the vote is faulty, the result can be still |
| | determined with a recount. |
| Smart food sensors | Tags that give information on the history of a product, like max |
| | temperature, humidity, duration of storage etc. |
| High-end sport circuitry | Low-weight sensors measuring, e.g., light level, temperature, wind, |
| | for use in gliders or boats. |
| Learning toys | Low-tech “computers” or “calculators” that perform simple tasks |
| | like Boolean algebra (if switch 1 and switch 3 are depressed, light 4 |
| | flashes). |
| Item pager | A set of tags that can be glued to items. Each tag identifies the item, |
| | e.g., keys, via RF-signal. This product is similar to the RF-tag, but |
| | each tag, e.g., #1-#99, have different resonance frequencies (˜100- |
| | 200 MHz). A reader indicates in which direction the item is located. |

Yet another aspect of the invention is directed to a mechanical device comprising of at least two components. The components include a pattern of a material applied to a substrate, comprising applying a first pattern of a first material to the substrate, that may or may not be followed by the application of a second material to the substrate and the first material. A second pattern of the second material is spontaneously formed on the substrate due to the interactions between the first material, the second material, and the substrate. Furthermore, the components are oriented such that the patterns oppose each other, and are identical patterns, inverse patterns, or any mechanically useful combination of patterns. In certain embodiments, the material comprises toner ink.

Several specific embodiments of mechanical devices of the invention include micro-fluidic channels, seals, snap-in fittings, keypads, and touch-pads.

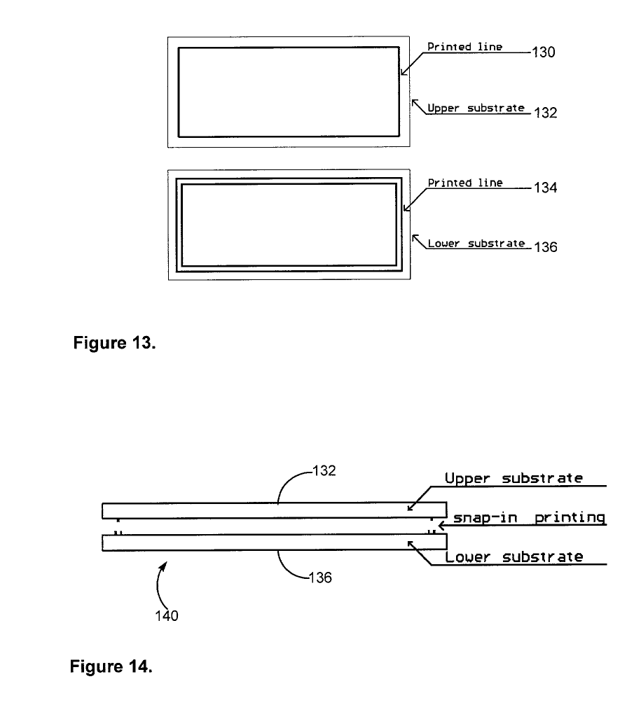

One embodiment of a mechanical device in accordance with the invention is a mechanical seal that comprises two components, in which each component comprises a substrate with a pattern of material thereon, as shown in FIG. 13. These patterns are prepared as toner ink patterns, electrophotographically deposited by a laser printer onto the substrates, and the two patterns are aligned in the manner described in Example 19. Those skilled in the art will appreciate that if the device was heated above the melting point of the printing ink, the ink can work as a sealant, itself, after cooling without use of any adhesive. This embodiment may also be used to provide a cavity outlined by the printed area for safely storing a liquid or powder. These cavities also can be used to direct liquids, gases, or other mobile materials between these substrates, e.g., micro-fluidic channels. The flow of mobile materials through the device can be adjusted by application of pressure or bending. Applications of such a device include displays; electronic circuits or assemblies, e.g., directed or timed application of drugs, application of different dielectrics into capacitors or actuators, and information carrying materials for sensor applications; mechanical assemblies, e.g., flow-detectors where a wheel is turned by the flow of a liquid; and micro-fluidics.

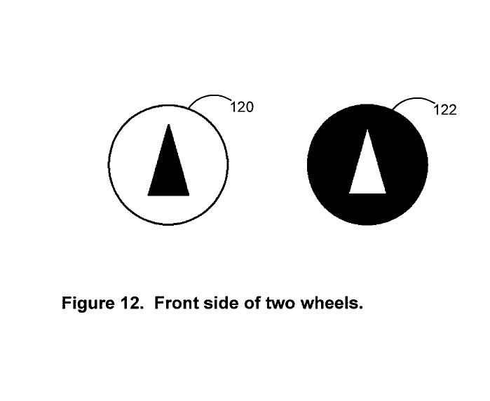

Another embodiment of a mechanical device, a snap-in fitting, utilizes a physical relationship between two inversely related patterns such that the patterns can be positioned to provide a physical interconnection, or fitting, between the patterns. The patterns compliment each other, such that the interconnection is made when one pattern snaps into the other. In certain embodiments, a snap-in fitting can comprise two components, with each component comprising a substrate with pattern, as shown in FIG. 12, that are prepared as toner ink patterns electrophotographically deposited by a laser printer onto the substrates. The two patterns are aligned in the manner described in Example 18. Those skilled in the art will appreciate that the surface structure can be accomplished either directly by printing or by the line patterning technique of the invention followed by the removal of the printing, depending on the desired qualities of the material. Alternatively, if the structure-giving material is resistive, the overlap or position of the device can be electrically measured. Applications of such a device include multiple stacked arrangements for one-time-counters, e.g., in disposable water filters, learning toys, intermediate reference coatings on devices to ensure quality of alignment in an assembly production process, and the like.

One embodiment of the invention, a freestanding film, is prepared by patterning an aqueous suspension of PEDOT-PSS, using a defined, e.g., rectangular, toner ink pattern electrophotographically deposited by a laser printer onto a substrate. The substrate is then placed in a beaker of toluene to detach the conducting polymer as a freestanding patterned polymer film. In an additional embodiment, the freestanding film is obtained from conducting polymers, biopolymers, or derivatives thereof. One of ordinary skill in the art will readily appreciate that the pattern can be coated with a material that aids in the release of the film from the substrate, that the substrate itself can be dissolved to release the film, and/or that the first pattern can be transferred to a second substrate by capturing the freestanding film on the second substrate. Applications of this technique include actuators, sensor devices (gas, liquid, or mechanical), generation of foils of conducting polymers, and parts of electronic devices incorporating thin films of the desired polymer.

In a specific embodiment of a freestanding film, in which polypyrrole is the conducting polymer, a current of 5 mA applied to the end of the film results in a contraction, slightly bending the flexible carrier substrate. One of ordinary skill in the art will readily appreciate that other conductive materials can be used and freestanding multiple layer arrangements can be prepared. Applications of this technique include miniature electromechanical devices, e.g., motors, actuators, and miniature robots.

In a specific embodiment of a freestanding film, an additional agent is incorporated into the conducting polymer to be patterned. In certain embodiments, the additional agent imparts sensitivity upon the freestanding film towards specific reactands. In a specific embodiment, ethylenediaminetetraacetic acid (EDTA) is the additional agent. In a particular embodiment, the EDTA is used to detect nickel(II), resulting in a change of the resistance of the freestanding film upon exposure. One of ordinary skill in the art will readily appreciate that different additional agents can impart different sensitivity to other reactands, that a matrix of different bends can be used to generate a specific pattern to identify, e.g., certain metal ions, and that optoactive compounds, e.g., phathalocyanines, can be used to prepare photoresistors. Applications of this technique include a disposable environmental sensor, e.g., for water quality, and a photometer.

In another embodiment of the invention, patterning can also be accomplished by coating a substrate, e.g., a transparent film, with a conducting material. In a particular embodiment, a pattern of a second material is then applied to the coating using a printing technique, and the remaining coating, not protected by the printed pattern, is chemically destroyed. The result is a conductive pattern covered by the second material. In one embodiment, the second material is an insulating toner ink. In another embodiment, the second material has a transmittance in the visible range. In certain embodiments, the conductive material is PEDOT-PSS.

### EXEMPLIFICATION OF THE INVENTION

Reference to the following illustrative examples was made for a more complete understanding of the invention. These examples are illustrative of preferred aspects of the invention and are not intended to limit the scope of the invention.

Experimental Apparatus

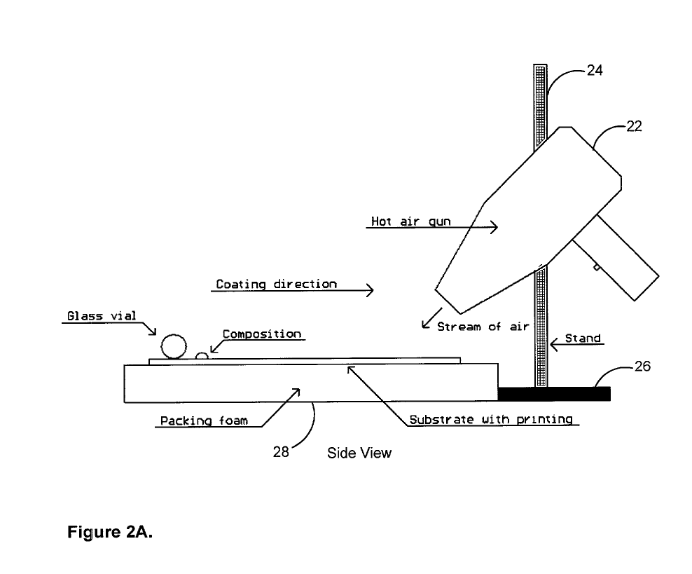

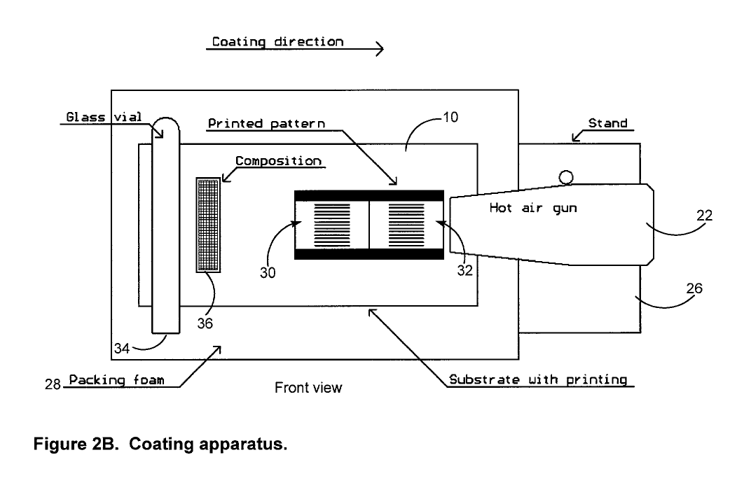

A schematic of a coating apparatus, used in accordance with the invention, is shown in profile view in FIG. 2a and in plan view in FIG. 2b. Two interdigitated patterns 30, 32 are disposed on the substrate 10 lying on packing foam 28. A glass vial 34 and composition 36 are disposed on the substrate 10. The coating apparatus includes a hot air gun 22 on a stand column 24 supported by a stand base 26. The operation of the coating apparatus shown in FIG. 2 is explained below in connection with the respective experimental examples.

### EXAMPLE 1

### Line Patterning Using a “2-Step” Process

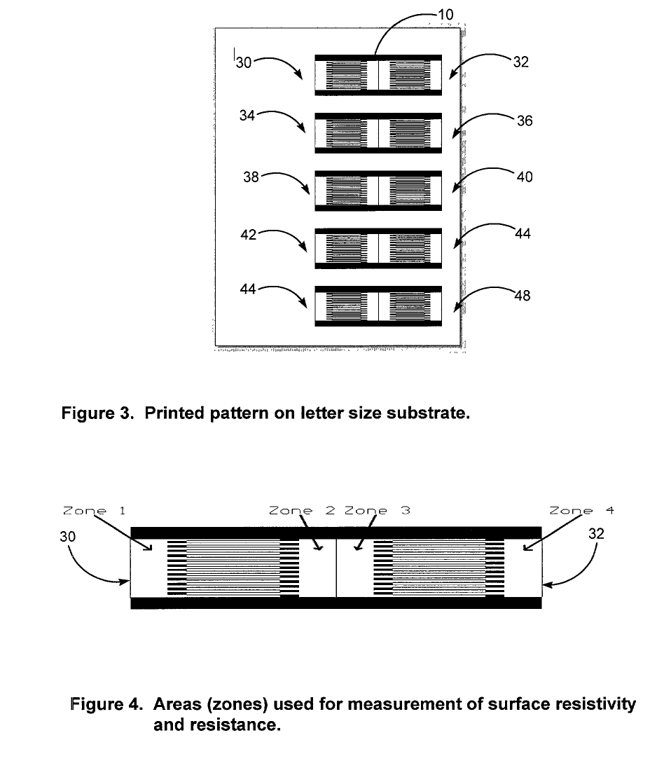

Referring to FIG. 3, ten interdigitated patterns 30, 32, . . . , 48 are shown. On a substrate 10 of the type set forth in Table 1, the ten interdigitated patterns 30-48 were printed using a printer as set forth in Table 1. The substrate 10 was cut horizontally into five equal partitions, each containing one row with two adjacent interdigitated patterns as shown in FIG. 4. Each partition, containing two identical patterns, shall be referred to herein as a “printed pattern”, and each individual interdigitated pattern shall be referred to herein as a “device”.

Referring to FIG. 4, the two interdigitated patterns 30, 32 are shown. The printed pattern of FIG. 4 was placed flat on a smooth and soft surface. The composition, 1 mL, (Table 1) was deposited 3 cm from the left edge of the printed pattern, as shown in FIG. 4.

In combination A (Table 1), the printed pattern was exposed to a stream of hot air, approximately 140 degrees C., during the deposition of the composition, i.e., the coating process. The hot air was generated using a hot air gun mounted as shown in FIG. 2. The deposited liquid composition (Table 1) was pushed over the printed pattern in one swipe using a glass vial, 2-5 seconds after turning on the hot air. The printed pattern was left standing for 10 seconds in the stream of hot air.

In the cases of combinations B, C and D (Table 1), the printed pattern was exposed to a stream of room temperature air during the coating process. The stream of air was generated using a hot air gun mounted as shown in FIG. 2, in which the heating circuit of the hot air gun had not been activated. The printed pattern was left standing for 10 seconds and the process of coating at room temperature was repeated an additional time.

After completion, the film was exposed to a stream of approximately 140 degrees C. hot air for 30 seconds generated using the hot air gun (FIG. 2).

The surface resistivity of several areas of the printed pattern (Zones 1, 2, 3, 4 of FIG. 4) and absolute resistance between adjacent areas (Zone 1-2, 2-3, 3-4) was measured using the apparatus of FIG. 1.

TABLE 1
Comparison of printer-substrate-coating combinations to number of
faults and surface resistivity.

| | | | | | Ave. Surface |
|---|---|---|---|---|---|
| | | | Com- | | Resistivity |
| | Printer | Substrate | position | Faults*¹ | [Ω/□] |
| A | LaserJet 5000N | Nashua XF-20 | BED1 | 3 of 10 | 14.7 k |
| B | LaserJet 5000N | Weyerhaeuser | BE1 | 4 of 10 | 744 k |
| | | paper | | | |
| C | Tektronix Phaser | Tektronix | BE1 | 0 of 10 | 1456 k |
| | 350 | paper | | | |
| D | Tektronix Phaser | Weyerhaeuser | BE1 | 1 of 10 | 417 k |
| | 350 | paper | | | |

*¹Unintentional electrical connections between areas outlined by the printing were considered to be faults. Ω/□ = Ohms/square

It was observed that the compositions were preferably deposited on the unprinted spaces of the substrate. The deposited film showed an average surface resistivity as listed in Table 1, for the respective printer-substrate-coating combinations. Furthermore, it was also observed that the compositions did not deposit, or at least insufficiently deposited, on the printed areas of the printed pattern. The printed areas showed an average surface resistivity out of measurement range (>20,000 kilo ohms) and therefore were considered to electrically insulate the unprinted, coated areas of the substrate outlined by this printing. Additionally, the Fluke 77 ohm meter, shown in FIG. 1, was used to measure the resistance between each individual Zone 1-2, 2-3, 3-4 (FIG. 4). The results of these measurements are shown in Table 3 as being out of measurement range.

The interdigitated pattern can be used in a number of ways as will be depicted in subsequent sections. The experimental data, for the respective samples of example 1, is set forth below in Tables 2-9.

TABLE 2
BED1 composition coating cast in hot stream of air
(approximately 140 degrees C.) on Nashua transparency, LaserJet 5000N

| Sample | Zone 1 | | | Zone 2 | | | Zone 3 | | | Zone 4 | | |
|---|---|---|---|---|---|---|---|---|---|---|---|---|
| ID | mV | μA | Ω/□ | mV | μA | Ω/□ | mV | μA | Ω/□ | mV | μA | Ω/□ |
| sama1 | 79 | 14 | 25.3 k | 65 | 27 | 10.8 k | 36 | 10 | 16.2 k | 30 | 11 | 12.3 k |
| sama2 | 42 | 7 | 27.0 k | 54 | 23 | 10.6 k | 73 | 17 | 19.3 k | 67 | 15 | 20.1 k |
| sama3 | 67 | 21 | 14.4 k | 81 | 34 | 10.7 k | 52 | 23 | 10.2 k | 71 | 29 | 11.0 k |
| sama4 | 36 | 6.8 | 23.8 k | 76 | 30 | 11.4 k | 65 | 36 | 8.1 k | 70 | 38 | 8.3 k |
| sama5 | 37 | 10 | 16.7 k | 53 | 23 | 10.4 k | 62 | 24 | 11.6 k | 96 | 38 | 11.4 k |
| Average | | | 21.4 k | | | 10.8 k | | | 13.8 k | | | 12.6 k |

Ω/□ = Ohms/square

TABLE 3
Double-check with Fluke 77

| Sample | Connection | Connection | Connection | Meter reading in |
|---|---|---|---|---|
| ID | Zone 1-2 | Zone 2-3 | Zone 3-4 | Zone 3 |
| sama1 | no | no | no | 25.8k |
| sama2 | no | no | no | 39k |
| sama3 | no | no | 140k | 18k |
| sama4 | no | no | no | 13k |
| sama5 | 4600k | no | 320k | 15k |

no: measure of absolute resistance out of measurement range (>20000k)

The results reported, in Tables 2 and 3, indicate that coating with composition BED1 yields reliable coatings on polyethyleneterephtalate transparency film (Nahshua XF-20). Additionally, the variations of the surface resistivity are within acceptable limits, e.g., varying by a factor of 2. As shown above in Table 3, 3 of 10 devices showed unintentional inter-connections.

TABLE 4
BE1 composition, 2 coatings cast under stream of air at room temperature,
then immediately exposed to hot stream of air (approximately 140 degrees C.)
on Weyerhaeuser paper for photocopiers, LaserJet 5000N

| | Zone 1 | | | Zone 2 | | | Zone 3 | | | Zone 4 | | |
|---|---|---|---|---|---|---|---|---|---|---|---|---|
| ID | MV | μA | Ω/□ | mV | μA | Ω/□ | mV | μA | Ω/□ | mV | μA | Ω/□ |
| samb1 | 550 | 1.5 | 1650 k | 530 | 3.8 | 630 k | 460 | 3.0 | 690 k | 605 | 3.0 | 908 k |
| samb2 | 625 | 4.0 | 730 k | 540 | 9.5 | 260 k | 397 | 6.9 | 259 k | 530 | 4.8 | 497 k |
| samb3 | 630 | 1.4 | 2030 k | 680 | 4.4 | 695 k | 307 | 2.1 | 658 k | 820 | 3.9 | 946 k |
| samb4 | 430 | 2.0 | 970 k | 1040 | 9.0 | 520 k | 396 | 4.4 | 405 k | 410 | 3.2 | 576 k |
| samb5 | 591 | 2.7 | 990 k | 799 | 8.8 | 410 k | 589 | 5.7 | 465 k | 619 | 4.7 | 593 k |
| Ave. | | | 1274 k | | | 503 k | | | 495 k | | | 704 k |

Ω/□ = Ohms/square

TABLE 5
Double-check with Fluke 77 digital ohm meter

| Sample | Connection | Connection | Connection | Meter reading |
|---|---|---|---|---|
| ID | Zone 1-2 | Zone 2-3 | Zone 3-4 | in Zone 3 |
| samb1 | no | no | 17000k | 980k |
| samb2 | no | no | 4900k | 440k |
| samb3 | no | no | no | 1500k |
| samb4 | no | no | 15300k | 1500k |
| samb5 | no | no | 15300k | 940k |

no: measure of absolute resistance out of measurement range (>20000k)

The results reported above, in Tables 4 and 5, indicate that coating with composition BE1 yields high resistance coatings on standard paper for photocopiers (Weyerhaeuser). The variations of the surface resistivity may have resulted from several sources of experimental error, such as, 1) the entirely manual coating process, 2) the coarseness of the paper, 3) inhomogeneity within the stream of air, and/or 4) experimental error associated with the measurement equipment. As shown above in Table 5, 4 out of 10 devices showed unintentional inter-connections.

TABLE 6
BE1 composition, 2 coatings cast under stream of air at room temperature,
then immediately exposed to hot stream of air (approximately 140 degrees C.)
on Tektronix paper for Tektronix Phaser printer.

| | Zone 1 | | | Zone 2 | | | Zone 3 | | | Zone 4 | | |
|---|---|---|---|---|---|---|---|---|---|---|---|---|
| ID | MV | μA | Ω/□ | mV | μA | Ω/□ | mV | μA | Ω/□ | mV | μA | Ω/□ |
| samc1 | 586 | 1.3 | 2028 k | 730 | 2.3 | 1428 k | 450 | 1.7 | 1191 k | 700 | 2.0 | 1575 k |
| samc2 | 535 | 1.4 | 1720 k | 560 | 1.3 | 1938 k | 450 | 1.1 | 1840 k | 698 | 2.0 | 1571 k |
| samc3 | 425 | 1.1 | 1737 k | 750 | 3.0 | 1125 k | 560 | 2.1 | 1200 k | 500 | 1.8 | 1250 k |
| samc4 | 350 | 1.5 | 1050 k | 400 | 1.7 | 1058 k | 520 | 1.4 | 1671 k | 610 | 2.2 | 1248 k |
| samc5 | 720 | 1.7 | 1905 k | 560 | 2.0 | 1260 k | 295 | 1.1 | 1207 k | 495 | 2.0 | 1114 k |
| Ave. | | | 1688 k | | | 1362 k | | | 1423 k | | | 1352 k |

Ω/□ = Ohms/square

TABLE 7
Double-check with Fluke 77 digital ohm meter

| Sample | Connection | Connection | Connection | Meter reading |
|---|---|---|---|---|
| ID | Zone 1-2 | Zone 2-3 | Zone 3-4 | in Zone 3 |
| samc1 | no | no | no | 2300k |
| samc2 | no | no | no | 3900k |
| samc3 | no | no | no | 2600k |
| samc4 | no | no | no | 3600k |
| samc5 | no | no | no | 3100k |

no: measure of absolute resistance out of measurement range (>20000k)

The results reported above, in Tables 6 and 7, indicate that coating with composition BE1 yields high resistance coatings on Tektronix paper for a Tektronix Phaser printer. The variations of the surface resistivity may have resulted from several sources of experimental error, such as, 1) the entirely manual coating process, 2) inhomogeneity within the stream of air, and/or 3) experimental error associated with the measurement equipment. The paper was significantly smoother than the standard photocopier paper (Weyerhaeuser), but likely contained a hydrophobic pre-coating to better attract the Tektronix solid ink, and which repelled the water based coating composition of PEDOT-PSS. The high average surface resistivity is indicative of an inhomogeneous coating. As shown above in Table 7, 0 out of 10 devices showed unintentional interconnection.

One skilled in the art will appreciate that this example illustrates that the quality, e.g., surface resistivity, of the second pattern can be adjusted by adjusting the substrate surface.

TABLE 8
BE1 composition, 2 coatings cast under stream of air at room temperature,
then immediately exposed to hot stream of air (approximately 140 degrees C.)
on Weyerhaeuser paper for photocopiers, Tektronix Phaser printer.

| | Zone 1 | | | Zone 2 | | | Zone 3 | | | Zone 4 | | |
|---|---|---|---|---|---|---|---|---|---|---|---|---|
| ID | MV | μA | Ω/□ | mV | μA | Ω/□ | mV | μA | Ω/□ | mV | μA | Ω/□ |
| Samd1 | 650 | 5.3 | 551 k | 618 | 5.5 | 506 k | 540 | 4.0 | 608 k | 720 | 5.5 | 589 k |
| Samd2 | 640 | 4.6 | 626 k | 480 | 3.8 | 568 k | 680 | 4.9 | 624 k | 410 | 2.8 | 659 k |
| Samd3 | 650 | 5.0 | 585 k | 540 | 5.0 | 486 k | 910 | 8.4 | 488 k | 630 | 6.5 | 436 k |
| Samd4 | 650 | 12.7 | 230 k | 520 | 13.9 | 168 k | 320 | 9.5 | 152 k | 309 | 6.6 | 211 k |
| samd5 | 603 | 14.2 | 191 k | 730 | 12.1 | 271 k | 440 | 10.7 | 185 k | 595 | 13.7 | 195 k |
| average | | | 437 k | | | 400 k | | | 411 k | | | 418 k |

TABLE 9
Double-check with Fluke 77 digital ohm meter

| Sample | Connection | Connection | Connection | Meter reading |
|---|---|---|---|---|
| ID | Zone 1-2 | Zone 2-3 | Zone 3-4 | in Zone 3 |
| samd1 | 16300k | no | no | 1000k |
| samd2 | no | no | no | 1500k |
| samd3 | no | no | no | 790k |
| samd4 | no | no | no | 230k |
| samd5 | no | no | no | 320k |

no measure of absolute resistance out of measurement range (>20000k)

The results reported above, in Tables 8 and 9, indicate that coating with composition BE1 yields moderate resistance coatings on standard photocopier paper (Weyerhaeuser). The variations of the surface resistivity resulted from several sources of experimental error, such as, 1) the entirely manual coating process, 2) the coarseness of the paper, 3) inhomogeneity within the stream of air, and/or 4) experimental error associated with the measurement equipment. As shown above in Table 7, 1 out of 10 devices showed unintentional inter-connections.

### EXAMPLE 2

### Comparison of Line Patterning Using a “3-Step” Process Versus a “2-Step” Process

On a substrate of the type set forth in Table 10, 10 interdigitated patterns as shown in FIG. 3 were printed using a printer as listed in Table 10. The substrate was cut horizontally into five equal partitions, each containing one row with two adjacent interdigitated patterns as shown in FIG. 4. The printed pattern of FIG. 4 was placed flat on a smooth and soft surface. Each partition, containing two identical patterns, shall be referred to herein as a “printed pattern”, and each individual interdigitated pattern shall be referred to herein as a “device”.

The composition of Table 10, 1 mL, was deposited 3 cm from the left edge of the printed pattern, as shown in FIG. 4. The printed pattern was exposed to a stream of hot air, approximately 140 degrees C., during the deposition of the composition, i.e., the coating process. The hot air was generated using a hot air gun mounted as shown in FIG. 2. The deposited liquid composition of Table 10 was pushed over the printed pattern in one swipe using a glass vial, 2-5 seconds after turning on the hot air. The printed pattern was left standing for 10 seconds in the stream of hot air.

In the case of the samples SAME 1-SAME5 (on Weyerhaeuser paper), the process of coating was repeated, as described above, a second time. The surface resistivity in the areas of Zones 1, 2, 3 and 4 (FIG. 4) and the absolute resistance between adjacent areas (Zone 1-2, 2-3, 3-4) were measured using the apparatus of FIG. 1. The deposited film showed an average surface resistivity as listed in Table 10. Additionally, the absolute resistance measurements allowed for the determination of unintentional electrical connections between adjacent areas outlined by the printing. Details of the comparison experimentation between the “2-Step” (SAME1-SAME5) and corresponding “3-Step” (SAMF1-SAMF5) processes of line patterning are described below.

TABLE 10
Dependence printer-substrate-coating to number of faults and surface
resistivity before removal of the printed line.

| | | | | | Ave. Surface |
|---|---|---|---|---|---|
| | | | Com- | | Resistivity |
| SAM | Printer | Substrate | position | Faults*¹ | [Ω/□] |
| E1-5 | LaserJet 5000N | Nashua XF-20 | BED1 | 3 of 10 | 13.6 k |
| G1-5 | LaserJet 5000N | Weyerhaeuser | BED1 | 10 of 10 | 181 k |
| | | paper | | | |

*¹Electrical connections between areas outlined by the printing were considered faults.

The coated patterns were placed into a toluene filled beaker and exposed to sonication for 60 seconds. The coated patterns were then waved in clean toluene for 10 seconds. The toluene soaked printed patterns were dried under a stream of air, of approximately 140 degrees C., for 10 seconds using the apparatus of FIG. 2. It was observed that the major part of the printing ink was removed from the substrate during this process. Furthermore, it was evident that the height of the printed parts of the pattern was reduced to a value below 1 μm, compared to the original printing height of approximately 5 μm. The resistivity and resistance measurements were repeated as described above and are listed in Table 11. It was determined that the average surface resistivity of the coated film on the unprinted region of the substrate demonstrated insignificant change as compared to average surface resistivity before sonication of the coated pattern in toluene. Additionally, the number of electrical interconnections between areas outlined by the printed pattern (Zone 1, 2, 3, & 4) was determined to be significantly reduced, i.e., the number of faults in Tables 10 and 11 were compared.

TABLE 11
Dependence printer-substrate-coating to number of faults and surface
resistivity after removal of the printed line.

| | | | | | Ave. Surface |
|---|---|---|---|---|---|
| | | | Com- | | Resistivity |
| SAM | Printer | Substrate | position | Faults*¹ | [Ω/□] |
| F1-5 | LaserJet 5000N | Nashua XF-20 | BED1 | 0 of 10 | 14.9 k |
| H1-5 | LaserJet 5000N | Weyerhaeuser | BED1 | 1 of 10 | 197 k |
| | | paper | | | |

*¹Electrical connections between areas outlined by the printing were considered faults.

TABLE 12
BED1 composition coating cast in hot stream of air (approximately
140 degrees C.) on Nashua transparency, LaserJet 5000N

| Sample | Zone 1 | | | Zone 2 | | | Zone 3 | | | Zone 4 | | |
|---|---|---|---|---|---|---|---|---|---|---|---|---|
| ID | mV | μA | Ω/□ | mV | μA | Ω/□ | mV | μA | Ω/□ | mV | μA | Ω/□ |
| same1 | 63 | 11 | 25.8 k | 42 | 19 | 9.9 k | 44 | 12 | 16.5 k | 71 | 25 | 12.8 k |
| same2 | 59 | 11 | 24.1 k | 71 | 28 | 11.4 k | 71 | 20 | 16.0 k | 79 | 25 | 14.2 k |
| same3 | 76 | 15 | 22.8 k | 86 | 47 | 8.2 k | 104 | 35 | 13.4 k | 78 | 40 | 8.8 k |
| same4 | 80 | 21 | 17.1 k | 73 | 33 | 10.0 k | 68 | 31 | 9.9 k | 86 | 48 | 8.1 k |
| same5 | 85 | 23 | 16.6 k | 35 | 19 | 8.3 k | 83 | 37 | 10.1 k | 83 | 50 | 7.4 k |
| average | | | 21.4 k | | | 9.6 k | | | 13.2 k | | | 10.3 k |

Ω/□ = Ohms/square

TABLE 13
Double-check with Fluke 77 digital ohm meter

| Sample | Connection | Connection | Connection | Meter reading |
|---|---|---|---|---|
| ID | Zone 1-2 | Zone 2-3 | Zone 3-4 | in Zone 3 |
| same1 | no | no | no | 30k |
| same2 | no | no | no | 24k |
| same3 | 155k | 210k | 61k | 20k |
| same4 | no | no | no | 19k |
| same5 | no | no | no | 16k |

no measure of absolute resistance out of measurement range (>20000k)

The results obtained were consistent with the results obtained for SAMA 1 -SAMA5. As shown above in Table 13, 3 devices out of 10 devices showed unintentional inter-connections. The average surface resistivity of the coating on the unprinted regions of the substrates was 13.6 k Ω/square.

TABLE 14
Experimental results after removal of the printed line by sonication in toluene
for 60 seconds and drying afterwards for 10 seconds in a stream of approximately
140 degrees C. hot air (on Nashua transparency, LaserJet 5000N).

| | Zone 1 | | | Zone 2 | | | Zone 3 | | | Zone 4 | | |
|---|---|---|---|---|---|---|---|---|---|---|---|---|
| ID | MV | μA | Ω/□ | MV | μA | Ω/□ | MV | μA | Ω/□ | mV | μA | Ω/□ |
| samf1 | 38 | 6.2 | 28.5 k | 25 | 12 | 9.4 k | 69 | 19 | 16.3 k | 70 | 25 | 12.6 k |
| samf2 | 64 | 11 | 26.2 k | 84 | 22 | 17.2 k | 75 | 19 | 17.7 k | 52 | 22 | 10.6 k |
| samf3 | 52 | 11 | 21.3 k | 74 | 35 | 9.5 k | 85 | 29 | 13.2 k | 67 | 32 | 9.4 k |
| samf4 | 99 | 18 | 24.8 k | 66 | 27 | 11.0 k | 66 | 27 | 11.0 k | 67 | 32 | 9.4 k |
| samf5 | 67 | 15 | 20.1 k | 75 | 34 | 9.9 k | 68 | 30 | 10.2 k | 78 | 40 | 8.8 k |
| Average | | | 24.2 k | | | 11.4 k | | | 13.7 k | | | 10.2 k |

Ω/□ = Ohms/square

TABLE 15
Double-check with Fluke 77 digital ohm meter

| Sample | Connection | Connection | Connection | Meter reading |
|---|---|---|---|---|
| ID | Zone 1-2 | Zone 2-3 | Zone 3-4 | in Zone 3 |
| samf1 | no | no | no | 31k |
| samf2 | no | no | no | 31k |
| samf3 | no | no | no | 25k |
| samf4 | no | no | no | 23k |
| Samf5 | no | no | no | 21k |

no measure of absolute resistance out of measurement range (>20000k)

The removal of the printed line by sonication in toluene demonstrates three primary results:

1) The surface resistivity of the coating on the unprinted regions of the substrates was not significantly changed. The average surface resistivity was 14.9 k Ω/square versus 13.6 k Ω/square measured before the removal of the printed lines. 2) The number of faults (unintentional connections within device) was reduced from 3, before the removal of the printed lines, to 0 after the removal of the printed lines. This supports the notion that connections between different zones occur via “bridges” over the printed lines. These “bridges” were removed together with the printed line when exposed to sonication in toluene. 3) The black printed lines exhibited a height of approximately Sum above the surface. After removal, the color of the lines had nearly vanished and the height was reduced to a value below the measurement limit of the available micrometer (less than 1 μm).

TABLE 16
BED1 composition, 2 coatings cast under hot air (approximately
140 degrees C.) on Weyerhaeuser paper printed with HP LaserJet 5000N.

| | Zone 1 | | | Zone 2 | | | Zone 3 | | | Zone 4 | | |
|---|---|---|---|---|---|---|---|---|---|---|---|---|
| ID | mV | μA | Ω/□ | MV | μA | Ω/□ | mV | μA | Ω/□ | mV | μA | Ω/□ |
| samg1 | 107 | 1.6 | 301 k | 65 | 1.2 | 244 k | 60 | 1.3 | 208 k | 77 | 1.4 | 248 k |
| samg2 | 250 | 3.8 | 296 k | 182 | 7.0 | 117 k | 250 | 8.8 | 128 k | 298 | 6.1 | 220 k |
| samg3 | 237 | 5.9 | 180 k | 216 | 7.0 | 139 k | 150 | 4.5 | 150 k | 150 | 5.1 | 132 k |
| samg4 | 249 | 4.5 | 249 k | 260 | 9.3 | 126 k | 140 | 5.4 | 117 k | 160 | 5.2 | 138 k |
| samg5 | 150 | 4.0 | 169 k | 195 | 6.1 | 144 k | 221 | 8.3 | 120 k | 244 | 5.8 | 189 k |
| Average | | | 239 k | | | 154 k | | | 145 k | | | 185 k |

Ω/□ = Ohms/square

TABLE 17
Double-check with Fluke 77 digital ohmmeter

| Sample | Connection | Connection | Connection | Meter reading |
|---|---|---|---|---|
| ID | Zone 1-2 | Zone 2-3 | Zone 3-4 | in Zone 3 |
| samg1 | 1100k | 590k | 880k | 350k |
| samg2 | 460k | 250k | 400k | 260k |
| samg3 | 480k | 340k | 370k | 210k |
| samg4 | 390k | 215k | 330k | 180k |
| samg5 | 440k | 280k | 450k | 150k |

no: measure of absolute resistance out of measurement range (>20000k)

The average surface resistivity was 181 k Ω/square, which was improved relative to the results of the analogous samples, SAMB 1-SAMB5, that yielded an average of 744 k Ω/square. Although different coating conditions were used, BE1 instead of BED1 and cold instead of heat, SAMB 1-SAMB5 used similar materials.

As shown above in Table 17, 10 devices out of 10 devices showed unintentional inter-connections. This indicates that the coating conditions have a strong influence on the number of faults and the quality of the coated film. Furthermore, the conditions can be adjusted to generate a high yield of fault-free devices.

TABLE 18
BED1 composition, 2 coatings cast under hot air (approximately
140 degrees C.) on Weyerhaeuser paper printed with HP Laserjet 5000N.
The printed lines are removed by 60 seconds of sonication in toluene.

| | Zone 1 | | | Zone 2 | | | Zone 3 | | | Zone 4 | | |
|---|---|---|---|---|---|---|---|---|---|---|---|---|
| ID | MV | μA | Ω/□ | MV | μA | Ω/□ | mV | μA | Ω/□ | mV | μA | Ω/□ |
| samh1 | 256 | 4.2 | 274k | 208 | 3.5 | 267k | 237 | 3.9 | 273k | 198 | 3.9 | 228k |
| samh2 | 192 | 3.2 | 270k | 200 | 5.5 | 164k | 193 | 5.9 | 147k | 239 | 4.9 | 219k |
| samh3 | 206 | 3.3 | 280k | 300 | 7.7 | 175k | 113 | 3.2 | 159k | 213 | 5.1 | 188k |
| samh4 | 140 | 2.6 | 242k | 182 | 8.4 | 98k | 128 | 5.1 | 113k | 319 | 6.3 | 228k |
| samh5 | 210 | 5.2 | 182k | 116 | 4.1 | 127k | 83 | 3.2 | 117k | 193 | 4.5 | 193k |
| Average | | | 250k | | | 166k | | | 161k | | | 211k |

Ω/□ = Ohms/square

TABLE 19
Double-check with Fluke 77 digital ohmmeter

| Sample | Connection | Connection | Connection | Meter reading |
|---|---|---|---|---|
| ID | Zone 1-2 | Zone 2-3 | Zone 3-4 | in Zone 3 |
| samh1 | no | no | no | 380k |
| samh2 | no | no | no | 220k |
| samh3 | no | no | no | 240k |
| samh4 | no | no | no | 180k |
| samh5 | no | no | 6000k | 140k |

no measure of absolute resistance out of measurement range (>20000k)

The surface resistivity of the coating on the unprinted regions of the substrates was not significantly changed relative to the coating on these regions before the removal of the printed lines. The average surface resistivity was 197 k Ω/square, as compared to 18 1 k Ω/square before the removal of the printed line. The negligible change in the surface resistivity indicates that the sonication in toluene does not harm the coating. As shown above in Table 19, 1 device out of 10 devices showed unintentional inter-connections after the removal of the printed lines using toluene and sonication. This was an improvement of 90% relative to the unintentional inter-connections detected before removal of these lines. This reduction of the number of faults, consistent with SAME1-5, supports the notion that unintentional connections occur via “bridges” over the printed line, which are removed together with the printed line.

The results for the present example, as stated above, indicate that the “3-Step” process results in the preparation of patterns containing more reliable insulating lines between the conductive coating on the substrate than were obtained with the“2-Step” process. The third step may be considered a repair of faulty devices to obtain a high yield of conductive patterns. The percent of faulty devices that are obtained is highly dependent upon the interaction properties among the first material, second material, and the substrate with respect to each other. Furthermore, it would be understood by one skilled in the art, that small improvements of application technique that result in reduction of the experimental errors, such as, 1) the entirely manual coating process, 2) the coarseness of the paper, 3) inhomogeneity within the stream of air, 4) experimental error associated with the measurement equipment, and/or 5) the composition of the second material, would result in a lower percentage of faulty devices.

### EXAMPLE 3

### Preparation of Chessboard Pattern Using a “2-Step” Process

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

II. The pattern shown in FIG. 4 was printed on 3M PP2500 transparency film for photocopiers (3M Corp., Austin, Tex.) using a HEWLETT-PACKARD LaserJet 4M (HEWLETT-PACKARD Corp., Model No. C2001A) and a new (not before used) Canon toner cartridge EP-E (Canon Corp. Japan, No. R74-1003-150).

III. 5 mL of an aqueous dispersion of poly-3,4-ethylenedioxythiophene-polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IV. The transparency described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

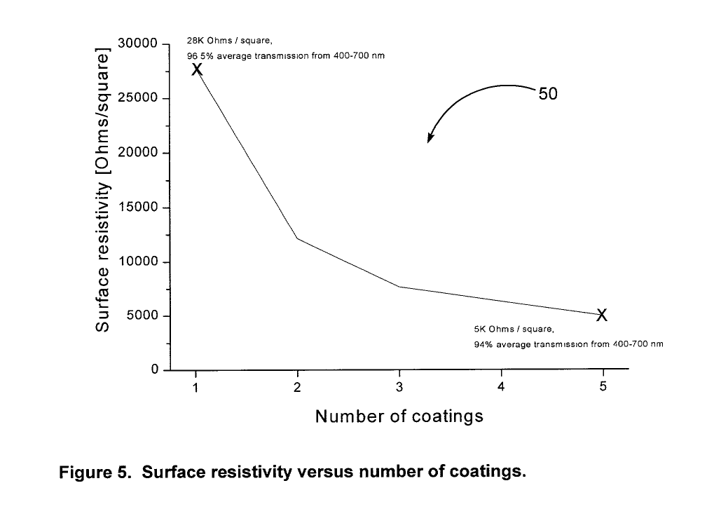

V. The surface resistivity of the dry coating was measured using the apparatus of FIG. 1. The process described in step IV was repeated until the surface resistivity was less than 20 kOhm/square, typically requiring one to three coatings. A plot of surface resistivity versus the number of coatings 50 is depicted in FIG. 5.

VI. The outline of printed and coated pattern was carefully cut from the transparency, and will be referred to as “electrode” in the following experimental details.

VII. A composition of 7 drops “Licristal E7” (Merck Corp., Germany), 3 drops NOA-65 optical adhesive (Norland Products, N.J.) and a small amount of 15 μm glass spacer (EM-Science, N.Y.) was mixed with a spatula in a glass Petri-dish until the composition became clear.

VIII. The electrode obtained in step VI was placed flat, printed side up, on a piece of paper. Two drops of the composition described in step VII were deposited in the middle of the electrode. A second electrode obtained in the same way as the first electrode described in step VI was placed, printed side down, onto the first electrode, aligning both electrodes orthogonally with symmetrically overlapping middle regions (symmetrical cross-like appearance). It was observed that the liquid composition described in step VII spread between the two electrodes, filling the entire overlapping area between the electrodes. The electrodes were allowed to stand until the complete overlapping area was filled with the composition. This assembly will be referred to as “device” in the following experimental details.

IX. The device obtained in step VIII was exposed to 366 nm light from a laboratory UV lamp at a distance of 6 cm for 20 minutes. The device was then flipped and again exposed to the UV light for an additional 20 minutes. The overlapping area containing the liquid crystal mixture, became opaque during this UV exposure process.

X. Silver pads were painted on the contact areas of the device (Zones 1, 2, 3,4, FIG. 4), using silver paint conductive paste (GC Thorsen Inc., Ill., No. 22-201). The silver paint was allowed to stand until it was dry (˜20 minutes at room temperature).

XI. With the help of 4 alligator clips, the 4 contact areas of the device were connected to 110 V AC, directly from the electrical mains. Two adjacent contact areas are supplied by one side of the electrical mains, one contact area from the first and one from the second electrode. The two remaining contact areas were connected to the other side of the electrical mains. The whole assembly was placed on a standard overhead projector, providing light to the device from below, for better visibility. The device exhibited a “chessboard pattern”, in which every other pixel was transparent or opaque, and all pixels were outlined by black printed lines.

### EXAMPLE 4

### Preparation of Chessboard Pattern Using a “3-Step” Process

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

II. The pattern shown in FIG. 4 was printed on Nashua XF-20 transparency film for photocopiers (Nashua Corp. N.H., No. 124831) using a HEWLETT-PACKARD LaserJet 4M (HEWLETT-PACKARD Corp., Model No. C2001A) and a new (not before used) Canon toner cartridge EP-E (Canon Corp. Japan, No. R74-1003-150).

IIIa. 2 mL of an aqueous dispersion of poly-3,4-ethylenedioxythiophene -polystyrenesulfonate (PEDOT-PSS, “Baytron P,” Bayer Corporation) were added to 4 mL of ethyleneglycol (Fisher Scientific) in a closed vial. The mixture was thoroughly shaken for 10 seconds, followed by 1 minute of sonication. The resulting composition was allowed to stand for 1 hour in air.

IIIb. 5 mL of an aqueous dispersion of poly-3,4-ethylenedioxythiophene -polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IVa. The transparency described in step II was placed flat, with its printed side up, on a piece of rubber foam (commonly used for packaging). Approximately 0.5 mL of the composition described in step IIIa was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

IVb. The process of step IVa was repeated using the composition of IIIb in substitution of the composition of IIIa.

V. The surface resistivity of the dry coating was measured using the apparatus of FIG. 1. The process described in step IVb was repeated until the surface resistivity was less than 20 kOhm/square, typically requiring one to three coatings. The quality of the coating, with respect to the resolution and homogeneity, on the Nashua transparency, was shown to increase using composition IIIa for the first coating.

VIa. The outline of printed and coated pattern was carefully cut from the transparency, and will be referred to as “electrode” in the following experimental details.

VIb. The electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2). The measured surface resistivity did not significantly change from the one determined in step V.

VII. A composition of 7 drops “Licristal E7” (Merck Corp., Germany), 3 drops NOA-65 optical adhesive (Norland Products, N.J.) and a small amount of 15 μm glass spacer (EM-Science, N.Y.) was mixed with a spatula in a glass Petri-dish until the composition became clear.

VIII. The electrode obtained in step VIb was placed flat, printed side up, on a piece of paper. Two drops of the composition described in step VII were deposited in the middle of the electrode. A second electrode obtained in the same way as the first electrode described in step VIb was placed, printed side down, onto the first electrode, aligning both electrodes orthogonally with symmetrically overlapping middle regions (symmetrical cross-like appearance). It was observed that the liquid composition described in step VII spread between the two electrodes, filling the entire overlapping area between the electrodes. The electrodes were allowed to stand until the complete overlapping area was filled with the composition. This assembly will be referred to as “device” in the following experimental details.

IX. The device obtained in step VIII was exposed to 366 nm light from a laboratory UV lamp at a distance of 6 cm for 20 minutes. The device was then flipped and again exposed to the UV light for an additional 20 minutes. The overlapping area containing the liquid crystal, became opaque during this UV exposure process.

X. Silver pads were painted on the contact areas of the device, or areas of the device with no overlapping of the electrodes, using silver paint conductive paste (GC Thorsen Inc., Ill., No. 22-201). The silver paint was allowed to stand until it was dry (˜20 minutes at room temperature).

XI. With the help of 4 alligator clips, the 4 contact areas of the device were connected to 110 V AC, directly from the electrical mains. Two adjacent contact areas are supplied by one side of the electrical mains, one contact area from the first and one from the second electrode. The two remaining contact areas were connected to the other side of the electrical mains. The whole assembly was placed on a standard overhead projector, providing light to the device from below, for better visibility. The device exhibited a “chessboard pattern”, in which every other pixel was transparent or opaque, and all pixels were outlined by black printed lines.

### EXAMPLE 5

### Preparation of a Heterogeneous Chessboard Pattern Using a “2-Step” Process

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

IIa. The pattern shown in FIG. 4 was printed on 3M PP2500 transparency film for photocopiers (3M Corp., Austin, Tex.) using a HEWLETT-PACKARD LaserJet 4m (HEWLETT-PACKARD Corp., Model No. C2001A) and a new (not before used) Canon toner cartridge EP-E (Canon Corp. Japan, R74-1003-150).

IIb. The pattern shown in FIG. 4 was printed on Weyerhaeuser laser copy paper (Item No. 1180) using a HEWLETT-PACKARD LaserJet 4m (HEWLETT-PACKARD Corp., Model No. C2001) and a new (not before used) Canon toner cartridge EP-E (Canon Corp. Japan, R74-1003-150).

III. 5 mL of an aqueous dispersion of poly-3,4-ethylenedioxythiophene-polystyrenesulfonate (PEDOT-PSS, “Baytron P,” Bayer Corporation) were added to 1mL of ethyleneglycol (Fisher Scientific) in a closed vial. The mixture was thoroughly shaken for 10 seconds, followed by 1 minute of sonication. The resulting composition was allowed to stand for 1 hour in air. IVa. The transparency described in step IIa was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than -10 seconds.

IVb. The paper described in step IIb was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than -10 seconds.

V. The surface resistivity of the dry coating of steps IVa and IVb were measured using the apparatus of FIG. 1. The process described in steps IVa and IVb was repeated until the coating on the unprinted areas of the transparency and the paper were less than 20 kOhm/square, typically requiring one to five coatings.

VIa. The outline of printed and coated pattern was carefully cut from the transparency, and will be referred to as “top electrode” in the following experimental details.

VIb. The outline of printed and coated pattern was carefully cut from the paper, and will be referred to as “bottom electrode” in the following experimental details.

VII. A composition of 7 drops “Licristal E7” (Merck Corp., Germany), 3 drops NOA-65 optical adhesive (Norland Products, N.J.) and a small amount of 15 μm glass spacer (EM-Science, N.Y.) was mixed with a spatula in a glass Petri-dish until the composition became clear.

VIII. The bottom electrode obtained in step VIb was placed flat, printed side up, on a piece of paper. Eight drops of the composition described in step VII were deposited in the middle of the electrode. The top electrode obtained in step VIa was placed, printed side down, onto the bottom electrode, aligning both electrodes orthogonally with symmetrically overlapping middle regions (symmetrical cross-like appearance). It was observed that the liquid composition described in step VII spread between the two electrodes, filling the entire overlapping area between the electrodes. The electrodes were allowed to stand until the complete overlapping area was filled with the composition. This assembly will be referred to as “device” in the following experimental details.

IX. The device obtained in step VIII was exposed to 366 nm light from a laboratory UV lamp at a distance of 6 cm for 20 minutes. The device was then flipped and again exposed to the UV light for an additional 20 minutes. The overlapping area containing the liquid crystal, became opaque during this UV exposure process.

X. Silver pads were painted on the contact areas of the device, or areas of the device with no overlapping of the electrodes, using silver paint conductive paste (GC Thorsen Inc., Ill., No. 22-201). The silver paint was allowed to stand until it was dry (˜20 minutes at room temperature).

XI. With the help of 4 alligator clips, the 4 contact areas of the device were connected to 110 V AC, directly from the electrical mains. Two adjacent contact areas are supplied by one side of the electrical mains, one contact area from the first and one from the second electrode. The two remaining contact areas were connected to the other side of the electrical mains. The whole assembly was placed on a standard overhead projector, providing light to the device from below, for better visibility. The device exhibited a “chessboard pattern”, in which every other pixel was transparent or opaque, and all pixels were outlined by black printed lines.

### EXAMPLE 6

### Removal of Unintentional Connections Between Insulated Device Areas

Several of the devices that were prepared contained unintentional connections between conductive areas that were designed to be insulated from one another. To determine such defects, the resistivity of each insulated area was measured versus each adjacent area using a digital multimeter, set within the 20 MOhms measurement range of the multimeter. If the reading of the multimeter was less than 20 MOhms, the insulated areas of the device were considered to contain an unintentional connection, or fault.

I. A large number of faults could be removed (˜80%) by applying a 400 V direct current (DC) potential between both unintentionally connected areas.

II. A large number of faults could be removed (˜90%) by removing the printed toner lines with the help of toluene and sonication as described in Example 4, step VIb.

### EXAMPLE 7

### Preparation of Chessboard Pattern Using a “3-Step” Process

I. The pattern shown in FIG. 4 was printed on 3M PP2500 transparency film for photocopiers (3M Corp., Austin, Tex.) using a HEWLETT-PACKARD LaserJet 4m (HEWLETT-PACKARD Corp., Model No. C2001A) and a new (not before used) Canon toner cartridge EP-E (Canon Corp. Japan, R74-1003-150). II. 3 mL of an aqueous dispersion of poly-3,4-ethylenedioxythiophene-polystyrenesulfonate (PEDOT-PSS, “Baytron P,” Bayer Corporation) were added to 3 mL of I-propanol (Fisher Scientific) in a closed vial. The mixture was thoroughly shaken for 10 seconds, followed by 1 minute of sonication. The resulting composition was allowed to stand for 1 hour in air.

III. The transparency described in step I was placed flat, with its printed side up, on a piece of rubber foam (commonly used for packaging). Approximately 0.5 mL of the composition described in step II was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

IV. The resistivity of each insulated area was measured versus each adjacent area using a digital multimeter, set within the 20 MOhms measurement range of the multimeter. If the reading of the multimeter was less than 20 MOhms, the insulated areas of the device were considered to contain an unintentional connection, or fault. It was determined that nearly all areas were unintentionally electrically connected.

V. These connections could be almost completely removed (˜90%) by removing the printed toner lines with the help of toluene and sonication as described in Example 4, step VIb. The connections are attributed to the presence of unintentional conductive “bridges” on the toner and the outlined areas. Therefore, the removal of the toner lines is accompanied by the removal of the conductive bridges positioned over the toner lines.

### EXAMPLE 8

### Line Patterning using Pyrrole

I. Distilled pyrrole, 1.5 mL, was added to 250 mL water in a 500 mL Erlenmeyer flask and stirred for 10 minutes, until the solution became homogeneous.

II. In a separate 500 mL Erlenmeyer-flask, 8.75 g FeCl₃*6H₂O and 5.7 g Ferric(III)toluenesulfonate (Fe(TOS)₃) were added to 250 mL water and dissolved under stirring for 10 minutes.

III. A piece of the printed transparency, as described in Example 4, step II, was placed into a 250 mL beaker. Under subsequent slow stirring with a magnetic stirrer, 100 mL of the solution of step I and 100 mL of the solution of step II were added to the 250 mL beaker, using a scissors-clip to hold the printed pattern completely submerged in the solution. The mixture was allowed to stir for 20 minutes at room temperature and under ambient atmospheric air, resulting in a black solution.

IV. The transparency was removed from the beaker in step III, dipped into distilled water, and kept submerged in the water, for 3 minutes, while moving it gently.

V. The transparency from step IV was dried for 1 minute with hot air (˜80° C.) provided by a hot-air-gun (FIG. 2).

VI. The surface resistivity of the printed areas (black toner lines/areas) of the pattern were measured to be ˜10 kOhms/square, while the semitransparent, unprinted, areas were measured to have a surface resistivity greater than 20 MOhms/square.

### EXAMPLE 9

### “3-Step” Line Patterning Using Pyrrole

I. Distilled pyrrole, 1.5 mL, was added to 250 mL water in a 500 mL Erlenmeyer flask and stirred for 10 minutes, until the solution became homogeneous.

II. In a separate 500 mL Erlenmeyer-flask, 8.75 g FeCl₃*6H₂O and 30 mL of a 1 molar HCl-water solution were added to 250 mL water and dissolved under stirring for 10 minutes.

III. A piece of the printed transparency, as described in Example 4, step II, was placed into a 250 mL beaker. Under subsequent slow stirring with a magnetic stirrer, 100 mL of the solution of step I and 100 mL of the solution of step II were added to the 250 mL beaker, using a scissors-clip to hold the printed pattern completely submerged in the solution. The mixture was allowed to stir for 20 minutes at room temperature and under ambient atmospheric air, resulting in a black solution.

IV. The transparency was removed from the beaker in step III, dipped into distilled water, and kept submerged in the water, for 3 minutes, while moving it gently.

V. The transparency from step IV was dried for 1 minute with hot air (˜80° C.) provided by a hot-air-gun (FIG. 2). VI. The surface resistivity of the printed areas (black toner lines/areas) of the pattern were measured to be ˜10 kOhms/square, while the semitransparent, unprinted, areas were measured to have a surface resistivity of ˜100 kOhms/square.

VII. The outline of printed and coated pattern was carefully cut from the transparency, and will be referred to as “electrode” in the following experimental details.

VIII. The electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2).

IIX. The surface resistivity of the previously printed areas of the pattern were measured to be greater than 20 MOhm/square, whereas the semitransparent, unprinted, areas did not significantly change in their measured surface resistivity.

### EXAMPLE 10

### Preparation of Semi-transparent Composites

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

II. The pattern shown in FIG. 4 was printed on Nashua XF-20 transparency film for photocopiers (Nashua Corp. N.H., No. 124831) using a HEWLETT-PACKARD LaserJet 4M (HEWLETT-PACKARD Corp., Model No. C2001A) and a new (not before used) Canon toner cartridge EP-E (Canon Corp. Japan, No. R74-1003-150).

III. 5 mL of an aqueous dispersion of poly-3,4-ethylenedioxythiophene-polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IV. The transparency described in step II was placed flat, with its printed side up, on a piece of rubber foam (commonly used for packaging). Approximately 0.5 mL of the composition described in step HI was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

V. The surface resistivity of the dry coating of step IV was measured using the apparatus of FIG. 1. The process described in step IV was repeated until the coating on the unprinted areas of the transparency and the paper were less than 20 kOhm/square, typically requiring one to three coatings.

VIa. Distilled pyrrole, 1.5 mL, was added to 250 mL water in a 500mL Erlenmeyer-flask and stirred for 10 minutes, until the solution became homogeneous.

VIb. In a separate 500 mL Erlenmeyer-flask, 8.75 g FeCl₃*6H₂O and 5.7 g Ferric(Ill)toluenesulfonate (Fe(TOS)₃) were added to 250 mL water and dissolved under stirring for 10 minutes.

VII. The printed transparency described in step V was placed into a 300 mL beaker. Under subsequent strong stirring with a magnetic stirrer, 150 mL of the solution of step VIa and 150 mL of the solution of step VIb were added to the 300 mL beaker, using a clamp to hold the printed transparency so that the stirrer could move freely. The mixture was allowed to stir for 20 minutes at room temperature and under ambient atmospheric air, resulting in a black solution.

VIII. The transparency was removed from the black mixture of step VII and was rinsed with a gentle stream of deionized water for 2 minutes. It was then immediately dried with ˜80° C. hot air provided by a hot-air-gun (FIG. 2).

IX. The outline of printed and coated pattern was carefully cut from the transparency, and will be referred to as “electrode” in the following experimental details.

X. The electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2).

XI. The surface resistivity of the semitransparent pattern, outlined by the printed pattern in FIG. 4, was measured using the apparatus of FIG. 1 to be 3×10³ Ohms/square. The surface resistivity of the printed pattern, after removal of the printed lines, was measured to be greater than 2×10⁷ Ohms/square (out of measurement range). The pattern generated by the above protocol represents a semi-transparent composite of two different conducting polymers on a flexible substrate.

XII. By repeated measurement of the resistance at different locations between the interdigitated regions of the conductive pattern of the electrode, an unintentional connection, causing an electric connection between both individual parts of the pattern, could be determined. The location of this connection, or fault, could be identified by following the direction of progressively smaller resistance towards the source of the unintentional connection. Alternatively, the connection could be identified by its contrast with respect to the background, when viewed under a microscope.

XIII. The connection, or fault, could be removed by a gentle cut with a razor blade into the conducting polymer.

### EXAMPLE 11

### Line Patterning on Paper

I. An 8″×5″ pattern of 40 square shaped boxes (1 cm×1 cm) was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4. 11. The pattern was printed on Weyerhaeuser paper for photocopiers using a HEWLETT-PACKARD LaserJet 4M (HEWLETT-PACKARD Corp., Model No. C2001A) and a Canon toner cartridge EP-E (Canon Corp. Japan, No. R74-1003-150).

III. 1 mL of an aqueous dispersion of poly-3,4-ethylenedioxythiophene-polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IV. The paper described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds. The coating process was repeated three times.

V. The surface resistivity of the dry coating was measured to be ˜600 kΩ/square within the squares, whereas infinite resistance was measured between two adjacent cells (out of measurement range, or greater than 20,000 kΩ/square). VI. The toner lines could be removed by sonication in toluene as described above in the Line Patterning “3-Step” Process described in Example 4, step VIb. No significant difference in surface resistivity was observed, relative to measurements made before the removal of the toner lines.

### EXAMPLE 12

### Line Patterning with Emeraldine Base

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern depicting two electrodes of 25 lines/inch is shown in FIG. 4.

II. The pattern shown in FIG. 4 was printed on 3M PP2500 transparency film for photocopiers (3M Corp., Austin, Tex.) using a HEWLETT-PACKARD LaserJet 4M (HEWLETT-PACKARD Corp., Model No. C2001A) and a new (not previously used) Canon toner cartridge EP-E (Canon Corp. Japan, No. R74-1003-150).

III. 5 mL of a solution of an emeraldine base (EB) in N-methyl-pyrrolidone (NMP), 0.5% by weight, was prepared by dissolving EB in NMP, sonicating for 1 hour, and subsequently filtering the resultant solution.

IV. The transparency described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

V. The electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2). The negative pattern of EB, with respect to FIG. 4, remained on the transparency.

### EXAMPLE 13

### Multi-layer Patterned Device

I. The interdigitated pattern of FIG. 4 was designed using “Protel Design Explorer 99” CAD-software (Protel International Corp., N.H.). The printed regions represent the non-conductive portions of the pattern, while the space outlined by the printed region represents the conductive part of the pattern. A sample pattern depicting two electrodes of 25 lines/inch is shown in FIG. 4.

II. The pattern shown in FIG. 4 was printed on 3M PP2500 transparency film for photocopiers (3M Corp., Austin, Tex.) using a HEWLETT-PACKARD LaserJet 4M (HEWLETT-PACKARD Corp., Model No. C2001A) and a new (not previously used) Canon toner cartridge EP-E (Canon Corp. Japan, No. R74-1003-150).

III. 6 mL of an aqueous dispersion of poly-3,4-ethylenedioxythiophene-polystyrenesulfonate (PEDOT-PSS, “Baytron P,” Bayer Corporation) were added to 1 L of ethyleneglycol (Fisher Scientific) in a closed vial. The mixture was thoroughly shaken for 10 seconds, followed by 1 minute of sonication. The resulting composition was allowed to stand for 1 hour in air.

IV. The transparency described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds.

V. Referring to FIG. 10, a coated pattern with orthogonal printing is shown. An additional interdigitated pattern, as depicted in FIG. 4, was printed on the transparency, orthogonal to the original interdigitated pattern, resulting in a pattern 370. Referring to FIG. 10, the coated pattern 370 with orthogonal printing and additional coating is shown. The coating process, as described in step IV, was repeated, providing a pattern 372.

VI. Referring to FIG. 11, a pattern after the removal of the toner lines is shown. The electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2). A negative pattern 380 of PEDOT-PSS, with respect to FIG. 10, remained on the transparency, as shown in FIG. 11.

VII. The device consisted of lines with a surface resistivity of ˜8 kΩ/square which were subdivided into square shaped areas with a surface resistivity of less than 5 kΩ/square. Those skilled in the art will appreciate that connection lines to the active areas of the device can be fabricated with less resistivity (and optical transmission) whereas the active part, e.g., the emitting area, of the device exhibits high transmission.

Also, connection lines can be fabricated with different materials compatible with the existing device, e.g., metal, using Line Patterning. In addition, multiple layer arrangements can be fabricated with different materials, e.g., conducting polymers, using the same technique.

### EXAMPLE 14

### Interconnections between Conductive and other Substrates

I. A hole was punched through commercially available PEDOT coated PET (Agfa) substrates using a standard office-type puncher.

II. Two substrates obtained in step I were aligned so that the holes overlapped and the conductive sides were positioned back to back, i.e., no physical connection between conductive sides.

III. Employing a set of crimping pliers, a grommet was placed through both of the aligned holes and pressed flat. As a result, the grommet was placed in contact with the respective conductive sides of the substrates so that a safe mechanical connection resulted. It was determined that the conductive sides of each substrate were electrically connected.

IV. Using a substrate as described in step I, a loop of copper wire was connected to one substrate using a set of crimping pliers with grommet. The copper wire was found to have electrical contact to the coated side of the substrate.

V. Those skilled in the art will appreciate that connections of this kind can be used for metal-polymer-junctions (ohmic and Schottky-type), and for a stable connection to other kinds of equipment, such as batteries used to supply the power to the substrate.

### EXAMPLE 15

### Thick Films of Polymers

I. An 8″×5″ pattern of 40 square shaped boxes (1 cm×1 cm) was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

II. The pattern was printed on a Nashua XF-20 transparency.

III. 6 mL of an aqueous dispersion of poly-3,4-ethylenedioxythiophene-polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IV. The transparency described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜100° C.) from a hot-air-gun of the type shown in FIG. 2, which was moved over the transparency several times, at a distance of 5 cm, for not longer than ˜10 seconds. The coating process was repeated several times, creating a thick film of PEDOT-PSS, ultimately utilizing ˜5 mL of the water dispersion of PEDOT-PSS. The thick coating on the substrate caused the device to appear nearly black to the naked eye.

II. After approximately 20 minutes, the dry electrode was dipped, using tweezers, into a 100 mL beaker filled with toluene and was sonicated. The electrode was flipped several times until the black toner lines were no longer apparent. After a time period of ˜20 seconds, the electrode was then dipped into a beaker with clean toluene and immediately dried with ˜80° C. hot air provided by a hot-air-gun (FIG. 2).

VI. The surface resistivity of the dry coating was measured to be less than 1000 Ω/square.

### EXAMPLE 16

### Line Patterning on Labels

I. An 8″×5″ pattern of 40 square shaped boxes (1 cm×1 cm) was designed using “Protel Design Explorer 99” CAD-software (Protel International Corp., N.H.). The printed regions represent the non-conductive portions of the pattern, while the space outlined by the printed region represents the conductive part of the pattern. A sample pattern for two electrodes suitable to display a “chessboard pattern” is shown in FIG. 4.

II. The pattern was printed on a Avery White Address Labels, #5260 Laser.

III. 5 mL of an aqueous dispersion of poly-3,4-ethylenedioxythiophene-polystyrenesulfonate (PEDOT-PSS, “Baytron P,” Bayer Corporation) were added to 1 mL of ethyleneglycol (Fisher Scientific) in a closed vial. The mixture was thoroughly shaken for 10 seconds, followed by 1 minute of sonication. The resulting composition was allowed to stand for 1 hour in air.

IV. The paper described in step II was placed flat, with its printed side up, on a piece of rubber foam (commonly used for packaging). Approximately 0.5 mL of the composition described in step III was deposited, drop-wise, close to one edge of the transparency using a pipette, forming a 5 cm long line of drops. A glass vial, 8 cm in length, was placed into this line of drops, moved slightly forward-and-backward to remove bubbles, and pushed with gentle force in one swipe (˜3 cm/second swiping speed) over the printed pattern. The wet coating was immediately exposed to hot air (˜80° C.) from a hot-air-gun of the type shown in FIG. 2, which was moved over the transparency several times, at a distance of 5 cm, for not longer than ˜10 seconds. The coating process was repeated three times.

V. The surface resistivity of the dry coating was measured to be ˜600 kΩ/square within the squares, whereas infinite resistance was measured between two adjacent cells (out of measurement range, or greater than 20,000 kΩ/square).

VI. The toner lines could be removed by sonication in toluene as described above in the Line Patterning “3-Step” Process described in Example 4, step VIb. After the label was dried with 100° C. air, no significant difference in surface resistivity was observed, relative to measurements made before the removal of the toner lines. Furthermore, it was determined that the label retained its functionality.

Those skilled in the art will appreciate that the method described with respect to the above examples can be extended to include the following modifications:

Different types of surfaces, e.g. PET, PP, PPE, PE and other plastic materials. Glass, Metal, Paper, Wood, Fabric, Quartz, Crystal, and Stone.

Different type of printing methods, e.g. Offset Printing with VanSon Tough-Tex Ink. Printing with a Tektronics Phaser-Printer. Silk-Screen printing. PhotoLithographic methods.

Different types of Inks and colours, e.g. VanSon Tough-Tex Ink. VanSon Infinity Ink. Oil based Inks and wax-based inks.

Different compositions of Inks, e.g. Mixtures of Baytron P with other solvents, e.g. glycerol, methanol, ethanol, butanol. Dispersions and solutions of polythiophene, polypyrrole and polyaniline, their derivatives and other conducting polymers.

Different types and compositions of polythiophene in concentrations and liquid compositions different from the ones in Baytron P.

### SAMPLE DEVICES MADE USING LINE PATTERNING TECHNIQUES

### EXAMPLE 17

### Solar Cell

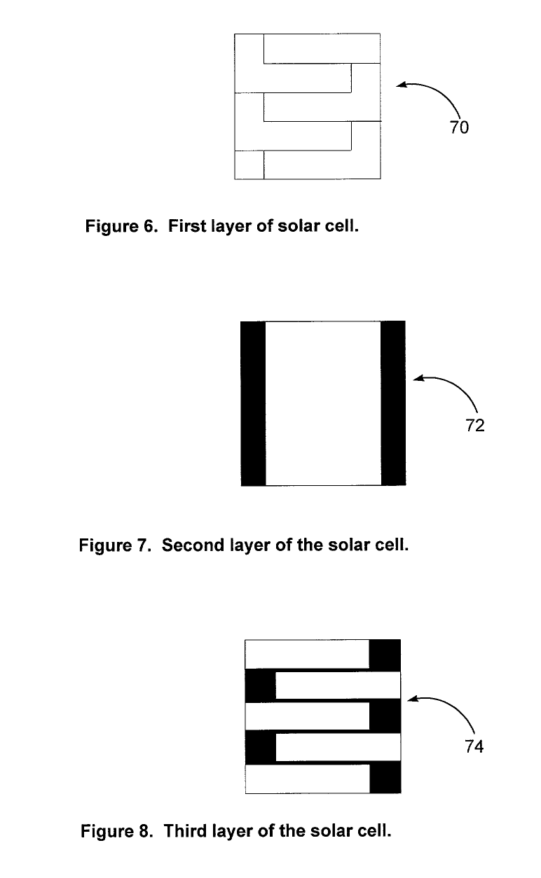

I. FIGS. 6-8 show a conductive pattern displaying a first layer 70, a second layer 72, and third layer 74 of a solar cell, respectively. The first pattern is prepared using the Line Patterning process of the invention using PEDOT-PSS (Composition BED1) in a process similar to the one described in Example 1A, on a transparent substrate, e.g., Nashua XF-20 overhead transparency. After coating with the transparent/semitransparent conductor, the printed lines are removed using the methodology described in Example 4, step VIb (sonication in toluene).

II. The pattern of the second layer 72, as shown in FIG. 7, is printed over the existing conductive pattern of the first layer 70 obtained from step I. The resulting, layered pattern is subsequently coated with a charge-separating compound that undergoes charge separation upon absorption of light, e.g., a substituted (R₈PcH₂), non substituted (PcH₂) or metal-phthalocyanine (PcMe) using Line Patterning as described above. The printed lines are removed after this step using the methodology described in Example 4, step VIb (sonication in toluene).

III. The pattern of the third layer 74, as shown in FIG. 8, is printed over the existing conductive pattern of the device obtained from step II. The device is subsequently coated with a conductor, e.g. aluminum or any other conducting or semi-conducting material, e.g. metals or indium/tin oxide (ITO), provided that it is different than the first conductor (to allow for charge separation). The printed lines are removed after this step using the methodology described in Example 4, step VIb (sonication in toluene).

IV. Referring to FIG. 9, a layered structure 90 of the solar cell of this example is shown. A transparency layer 92 lies at the bottom. A first PEDOT layer 94 is disposed on the transparency layer 92, and a phthalocyanine 96 is disposed onto the first PEDOT layer 94. A second conductive layer 98, e.g., aluminum, forms a top layer of the layered structure 90. Those skilled in the art will appreciate that a variety of materials are suitable for application in solar cells, e.g. amorphous silicon or organic materials as described in: C.J. Brabec, N.S. Sariciftici, J.C. Hummelen, Adv. Funct. Mater, 2001, 11, 15-26. “Plastic Solar Cells”. Other transparent or semitransparent substrates, e.g., Schott glass slides, and other conducting or semi-conducting materials, e.g., ITO and polypyrrole, can also be used in this process. In addition, solar cells with higher efficiency can be obtained by stacking these films or devices. Those skilled in the art will further appreciate that the device of FIG. 9 can be used as a background of a display. Applications of the solar cell 15 of FIG. 9 include light level sensors in cameras or shadow sensitive elements, e.g., for “touch-screens.”

### EXAMPLE 18

### Surface structures for simple mechanics.

I. Surface structures, as shown in FIG. 12, are prepared on a Nashua XF-20 transparency, utilizing the difference in height of the pattern, e.g., PEDOT-PSS, and the printed toner ink, e.g., from a laser printer (˜4.5 μm HP LaserJet 4M).

II. Referring to FIG. 12, the male circular pattern 120 fits into the female circular pattern 122 in only one orientation, resulting in a “snap-in” fitting. When the two pattern faces are pressed together, this “snap-in” fitting provides a mechanical link between the male circular pattern 120 and the female circular pattern 122. In all other orientations, one of the patterns can be turned or moved without causing the other pattern to turn or move. In this regard, several of these patterns can be used for applications, such as, disposable counters, where each pattern (wheel) represents the count of one full turn.

III. Those skilled in the art will appreciate that a variety of materials can be used for the substrate, e.g., glass, plastic, or ceramics; the first material, e.g., laser printer toner or Van Son ink for offset printers; and the second material, e.g., conducting polymers, insulating polymers, or sugars. In addition, any other method may be used that generates a pattern with a height that is distinct, e.g., more than 0.5 μm, from that of the substrate, such as the difference in height of coated/non-coated areas as obtained by the Line Patterning process of the invention. Those skilled in the art will also appreciate that the surface structure can be accomplished either directly by printing or by the Line Patterning technique of the invention followed by the removal of the printing, depending on the desired qualities of the material. The latter height is dependent on the coating material and the number of coatings. Alternatively, if the structure-giving material is resistive, the overlap or position of the device can be electrically measured. Applications of such a device include multiple stacked arrangements for one-time-counters, e.g., in disposable water filters, learning toys, intermediate reference coating on devices to ensure quality of alignment in an assembly production process, and the like.

### EXAMPLE 19

### Surface Structures to Seal/Align Electronic Devices

I. Referring to FIG. 13 printed lines 130, 136, an upper substrate 130, and a lower substrate 136 is shown. These surface structures are prepared on a Nashua XF-20 transparency, utilizing the difference in height of the pattern, e.g., PEDOT-PSS, and the printed toner ink, e.g., from a laser printer (˜4.5 μm HP LaserJet 4M).

II. An adhesive is deposited between the two black lines of the lower substrate 136. The height of the printed lines prevents spreading of the adhesive beyond the enclosed area.

III. The upper substrate 132 is positioned so that the printed side of the upper substrate 132 opposes the printed side of the lower substrate 136. The printed lines allow the substrates to be aligned manually, due to the clearly visible margins, and precisely, due to the complementary surface structure of the upper and the lower substrates. This process also provides a reliable seal with the adhesive, without risk of the adhesive spreading into undesired regions of the device.

Referring to FIG. 14, a side view 140 is depicted of the device shown in FIG. 13. The “snap-in” fitting of the device, useful in seal and alignment technology is illustrated.

IV. Those skilled in the art will appreciate that a variety of materials can be used for the substrate, e.g., glass, plastic, or ceramics; the first material, e.g., laser printer toner or Van Son ink for offset printers; and the second material, e.g., conducting polymers, insulating polymers, or sugars. In addition, any other method may be used that generates a pattern with a height that it distinct, e.g., more than 0.5 Jim, from that of the substrate, such as the difference in height of coated/non-coated areas as obtained by the Line Patterning process of the invention. Those skilled in the art will also appreciate that the surface structure can be accomplished either directly by printing or by the Line Patterning technique of the invention followed by the removal of the printing, depending on the desired qualities of the material. The latter height is dependent on the coating material and the number of coatings. Those skilled in the art will appreciate that if the device is heated above the melting point of the printing ink, the ink works as a sealant itself after cooling without use of any adhesive. This embodiment may also be used to provide a cavity outlined by the printed area for safely storing a liquid or powder until use. These cavities also can be used to direct liquids, gas or other mobile materials between these substrates. The flow of mobile materials through the device can be adjusted by application of pressure or bending. Applications of such a device include microfluidics, mechanical assemblies, e.g., flow-detectors where a wheel is turned by the flow of a liquid, displays, and electronic circuits or assemblies to align and/or seal devices from environmental influences, e.g., water, humidity, or gases.

### EXAMPLE 20

### Speaker/Buzzer

I. Referring to FIG. 15, two conductive patterns associated with an upper part 150 and a lower part 152 are shown. The upper part 150 and the lower part 152 are prepared using the Line Patterning process of the invention, using PEDOT-PSS (Composition BED1) in a process similar to the one described in Example 1A, on a flexible substrate, e.g., Nashua XF-20 overhead transparency. The printed lines are not removed, providing an height difference relative to the coated surface, and thus ensuring a separation of the two substrates of the device (upper and lower parts 150, 152 of FIG. 15).

II. The upper part 150 and lower part 152 of the device are aligned, conducting sides opposing each other, whereby the printed lines of the circle overlap, but the extending squares (contact areas) have different orientation. The resultant device, wherein the squares are oriented in opposite directions, is shown in FIG. 16, in a side view 160. A lower flexible substrate 162 and an upper flexible substrate are in contact with printed lines 168. On the inside surface of the upper flexible substrate 164 is disposed a positive contact 168, and on the inside surface of the lower flexible substrate 162 is disposed a negative contact 166.

III. When an alternating potential is applied, both parts of the device (upper and lower) attract and repel each other, relative to the polarity of the potential applied, as a result of the induced electrostatic force between the parts. When an appropriate frequency and voltage of the alternating potential and flexibility of the substrate is chosen, a sound is emitted from the device.

IV. Those skilled in the art will appreciate that other flexible or rigid substrates, e.g., Weyerhaeuser paper, Schott glass slides, and other conducting or semi-conducting materials, e.g., metal, ITO, or polypyrrole, can be used in this process. Those skilled in the art will also appreciate that the shape or size and material of the device can be used to cause resonance at specific frequency ranges. Additionally, when the resonance is strongly induced, a contact of both charged areas can occur resulting in an immediate, distinguishable, change in current flow into the device, which can be utilized to detect the specific frequency. Applications of such a device include speakers and frequency detectors in which the device appears to “deactivate” at specific frequencies as determined by the device dimensions.

### EXAMPLE 21

### Electrostatic Actuator Utilizing Flexible Substrates Coated with Conductor

I. Referring to FIG. 17, two conductive patterns are prepared using the Line Patterning process of the invention using PEDOT-PSS (Composition BED1) in a process similar to the ones described in Example 1A. The printed lines 170 can be disposed on a substrate 172, such as a flexible Nashua XF-20 overhead transparency. The printed lines 170 are not removed, providing an height difference relative to the coated surface, and thus ensuring a separation of the two substrates of the device (upper and lower parts of FIG. 15).

II. In FIG. 18, a side view of the device of FIG. 17 is shown. The printed lines 170 are sandwiched between a positive contact 174 and a negative contact 176. Both parts of the device are aligned, conducting sides opposing each other, whereby the printed lines 170 of the upper and lower parts overlap.

III. When a potential is applied, the middle of the device contracted as a function of the applied voltage. As a result of the bending middle region and the flexible connection between both sides, the edges, into which electrostatic forces are not induced, move in opposite directions.

IV. Those skilled in the art will appreciate that other flexible substrates, e.g., Weyerhaeuser paper, thin glass slides, and other conducting or semi-conducting materials, e.g., metal, ITO, or polypyrrole, can be used in this process. Those skilled in the art will also appreciate that such a device can be stacked to obtain a more developed lift or lowering, or that an insulator can be cast on or placed between the conductive sides to prevent sparks. Applications of such a device include an actuator for mechanical watches, mini-robots, e.g., actuators or movable parts, stirring or mixing in microfluidic applications, channeling the flow of reagents or test samples, microelectromechanicalsystems (MEMS), and light-beam adjustment/focusing for use in, e.g., an optical switch.

### EXAMPLE 22

### Conducting Polymer Fuse

I. As shown in FIG. 19, a conductive pattern 190 is prepared using the Line Patterning process of the invention, using PEDOT-PSS (Composition BED1) in a process similar to the one described in Example 1A and a Nashua XF-20 overhead transparency as a substrate. The number of coatings of PEDOT-PSS in this device is adjusted to exhibit an absolute resistance of 60 kOhm between the contacts “A” 192 and “B” 194.

II. An adjustable voltage is applied to a first contact 192, a second contact 194 is connected to ground, and the resistance between the first contact 192 and the second contact 194 is calculated from the applied voltage and the measured current flow through the device.

III. It is determined that at low current, e.g., 80 μA (5 V) the device does not significantly change its resistance over a period of 2 minutes. At medium current, e.g., 400 μA (30 V), the device permanently changes its resistance to a greater resistance, e.g., 400 kOhm, after several seconds as a complex function of the applied current (voltage) and time of exposure to this current. When high current, e.g., 6.6 mA (400 V) is attempted to be applied to the device, the device immediately increases its resistance, irreversibly, to a value greater than, e.g., 20,000 kOhm.

IV. Those skilled in the art will appreciate that other flexible or rigid substrates, e.g., Weyerhaeuser paper, Schott glass slides, and other conducting or semi-conducting materials, e.g., metal, ITO, or polypyrrole, can be used in this process. Those skilled in the art will also appreciate that the behavior of this device is dependent on the geometry and type of material that is used to construct the device. Applications of such a device include electric stress sensors, e.g., in “classic” electronic assemblies, detecting the location of the circuitry breakdown, and use as fuses.

### EXAMPLE 23

### Variable Resistor

I. Referring to FIGS. 20 and 21, conductive patterns are shown, according to the principles of the Line Patterning process of the invention using PEDOT-PSS (Composition BED1) in a process similar to the one described in Example 1A and a Nashua XF-20 overhead transparency as a substrate.

II. An upper substrate 202 and lower substrate 204 were aligned, conducting sides opposing each other, whereby the big black bars of printing ink were placed on top of each other.

III. A voltage, e.g., +5 V, and ground were applied to either end of the lower substrate. The potential difference was measured between the contact area of the upper substrate and ground.

IV. If sufficient pressure was applied to the middle of the device, e.g., via a movable lever, so that both of the conducting surfaces came into contact, it was discovered that the potential difference measured between the contact area of the upper substrate and ground was dependent upon the position of the pressure applied to the device.

V. Those skilled in the art will appreciate that other flexible or rigid substrates, e.g., Weyerhaeuser paper, Schott glass slides, and other conducting or semi-conducting materials, e.g., metal, ITO, or polypyrrole, can be used in this process. Those skilled in the art will also appreciate that the device can be designed as a circle to measure the position of the pressure within a turn instead of a longitudinal direction. The device could also be of almost any shape, and used to follow complex movements of the lever. Furthermore, the device could be bent into a variety of three-dimensional shapes to fit into a desired apparatus. Applications of such a device include a variable resistor, a variable capacitor (trimmer or padder), a position sensor in complex machinery, and a position sensor for electronic games, e.g., checkerboard games.

### EXAMPLE 24

### Circuitry Built in Integrated Circuit-sockets.

In many digital electronic applications it is desirable to maintain defined signal states even though it is not clearly defined what electronics will be attached to the circuitry at the time of design and operation. In general, such defined states are achieved by, so-called, “pull-down” or “pull-up” resistors, which are soldered close to the prospectively undefined inputs or outputs of an integrated circuit (IC) or assembly. In addition, these resistors prevent damage to the inputs resulting from electrostatic discharge when, e.g., accidentally touched. A typical resistance for each resistor is 47,000 Ohms. Furthermore, it is desirable to have a small capacitance, typically on the order of 100 pF, close to the power supply inputs of each IC to prevent malfunction due to instabilities in the power source. In most prototype applications, ICs are placed into sockets to enable an easy exchange, if damaged.

I. Referring to FIG. 22A-22C, a conductive device is shown that is formed on the plastic surface of a commercial dual-in-line 20 (DIL 20)-IC socket using the Line Patterning process of the invention, e.g., using a custom stamp to apply Van Son Tough-Tex Ink to apply the first pattern. PEDOT-PSS is then applied to the pattern using, e.g., a spraying technique with the water dispersion “Baytron P” (Bayer Corp) and is subsequently dried under ˜80° C. hot air using the apparatus in FIG. 2. In FIG. 22A, the conductive pattern 220 is shown. The pattern is created to ensure that the metal connections of the socket are in contact with the conductive areas of the pattern. Moreover, this pattern is specifically designed for an IC 74HC245. In FIG. 22B, a resistor schematic 222 of the conductive pattern 220 is shown. In FIG. 22C, a pin assignment 224 of the conductive pattern 220 is shown.

II. When the integrated circuit, 74HCT245, is plugged into the socket, all of the data pins (A1-A8; B1-B8) are connected to ground (Vss) via a resistor.

III. Those skilled in the art will appreciate that such circuitry can also be built onto the integrated circuit or onto the printed circuit board. In addition, by creating two overlapping but insulated areas, a capacitor can be created according to the methods of the invention that can be connected between the power supply pins of the integrated circuit. Applications of such circuitry includes improved electronic components that may be printed directly onto a substrate, upgrade of existing circuitry with new components, correction of design error by the addition of new components, and the application of protection to electrostatic discharge to specifically dedicated areas of electronic assemblies.

### EXAMPLE 25

### Hybrid Assembly as Component for Printed Circuit Boards

I. Referring to FIGS. 23A, a conducting polymer pattern 230 is shown. FIG. 23A includes printed lines 232 that form the pattern 230. These printed lines 230 are prepared using the Line Patterning process of the invention using PEDOT-PSS (Composition BED1) in a process similar to the one described in Example 1A and a Nashua XF-20 overhead transparency as a substrate.

Referring to FIG. 23B, a second conducting polymer pattern 234 is shown. The second conducting polymer pattern 234 is formed by printing a broad line 236 over the conducting polymer pattern 230.

II. The surface of the device is metallized using chemical, physical, or electrochemical deposition on the device 232, whereas metal deposition does not occur on the printed lines 236. The printed lines were subsequently removed using the methodology described in Example 4, step VIb (sonication in toluene).

III. Referring to FIG. 24, a schematic assembly 240 of an electronic device is shown. Commercially available, Y-shaped pins, are crimped to the contact pads of the device. The device represents a resistor array that can be soldered onto standard circuit boards. In FIG. 24B, a circuit schematic 242 corresponding to the assembly 240 is shown.

IV. Those skilled in the art will appreciate that other substrates, e.g., Weyerhaeuser paper, Schott glass slides, and other conducting or semi-conducting materials, e.g., metal, ITO, or polypyrrole, can be used in this process. Those skilled in the art will also appreciate that other electronic or mechanical components can be prepared in this manner of hybrid assembly and that low resistance connection lines can be achieved by using thick conducting polymer coatings instead of metallization. Applications of this technique include low cost hybrid electronic assemblies for printed circuit boards and integrated circuits with low weight and low profile.

### EXAMPLE 26

### 64 bit (8×8) One-Time Programmable Read Only Memory (OTP ROM) Element

I. FIG. 25 illustrates a conductive pattern 250 prepared using the Line Patterning process of the invention using PEDOT-PSS (Composition BED1) in a process similar to the one described in Example 1A and a Nashua XF-20 overhead transparency as a substrate. The printed lines are subsequently removed using the methodology described in Example 4, step VIb (sonication in toluene), and the second pattern 260, as shown in FIG. 26, is then printed over the first pattern.

II. The pattern is then coated with a solution of 0.5% (by weight) emeraldine base (EB) in N-methyl-pyrrolidinone (NMP) that is subsequently doped by exposure to fumes of 5 molar hydrochloric acid, forming a semiconductive emeraldine salt.

III. The pattern obtained in step 3 is coated with, e.g., a metal, e.g., aluminum or gold, using chemical, physical, or electrochemical deposition. The metal deposited on the emeraldine salt forms a diode, e.g., a Shottky contact. The printed lines are subsequently removed using the methodology described in Example 4, step VIb (sonication in toluene). Referring to FIG. 27, a side view 270, depicting the layered patterning of the device, is shown.

IV. The device, as obtained, represents an array of 64 diodes. When a positive voltage of, e.g., 5 V, is applied to one row of FIG. 26, the respective set of 8 diodes allow the potential to pass and the electrical pattern of 8×˜5 V is biased to the respective set of 8 columns of FIG. 25, e.g., the respective bits read 1 (high). On the other hand, when a diode is ‘destroyed’ e.g., by application of a excess current that is biased through one diode out of 64, that destroys the emeraldine-salt layer between the PEDOT and metal, the diode becomes an open circuit and the respective bit reads 0 (low). This results in a programmable device, such as can be seen in FIG. 27. This destruction is also achieved by area-specifically undoping the emeraldine salt with a base, e.g., by the application of a 0.1 molar aqueous solution of sodium hydroxide in droplets on specific diodes. During this process the proton doped emeraldine salt becomes locally neutral, or basic, and thus undoped as the base neutralizes the acid (protons).

V. Those skilled in the art will appreciate that other substrates, e.g., Weyerhaeuser paper, Schott glass slides, and other conducting or semi-conducting materials, e.g., metal, ITO, or polypyrrole, can be used in this process. Those skilled in the art will also appreciate that the device can be pre-programmed during construction and can be used to make memory for intelligent tags, memory for a variety of electronic circuitry, e.g., microprocessors and PROMs, a logical signal mixer, a programmable gate array logic (PAL/GAL), and a state machine.

### EXAMPLE 27

### Coil

I. As shown in FIG. 28, a conductive pattern 280 is prepared using the Line Patterning process of the invention using PEDOT-PSS (Composition BED1) in a process similar to the one described in Example 1A and a Nashua XF-20 overhead transparency as a substrate.

II. When a magnet is moved or rotated proximal to the conductive pattern, a current is induced into the coil. This can be utilized as a power source to supply power to electronics that are placed on the device, e.g., in the center of the device.

III. Those skilled in the art will appreciate that other substrates, e.g., Weyerhaeuser paper, Schott glass slides, and other conducting or semi-conducting materials, e.g., metal, ITO, or polypyrrole, can be used in this process. Those skilled in the art will also appreciate that the wheel conductive pattern 280 of FIG. 28 can be rotated around its middle axis in a static magnetic field to induce current into the coil. Additionally, exposure to an alternating magnetic field will produce a similar effect as rotation in this static magnetic field. Applications of such a device include a converter of rounds/minute into voltage, e.g., a speedometer, a power supply for electronic circuitry, and an ultra-light-weight motor, e.g., containing motor coils comprising patterns comparable to those described above.

Electronic Circuit Examples (General Characteristics)

Examples 28-31 relate to the manufacturing and characterisation of passive and active electronic components which can be used in different combinations to obtain printed electronic board assemblies (PCB assemblies) or integrated circuits (ICs). These devices incorporate a substrate, e.g., polyethyleneterephtalate (PET) and/or glass, one or more patterned/unpatterned electronic polymers, e.g., derived from a water dispersion of poly-3,4-ethylenedioxythiophene/polystyrenesulfonic acid (PEDOT/PSS, “Baytron P”, Bayer Corp.) as conductive/semiconductive layers and optional insulating layers/spaces, e.g. silicon oil, wax or adhesive.

### EXAMPLE 28

### Preparation of Resistor-like Devices with a Well Defined Resistance

I. Referring to FIG. 29, a pattern of PEDOT-PSS 290 was prepared by the Line Patterning (LP) process described above using PEDOT-PSS (Composition BED1) in a process similar to the one described in Example 1A and a Nashua XF-20 overhead transparency as a substrate. Black printed areas 292 that are covered by toner, represent the insulating part of the device, while the white dumbbell-shaped areas 294 represent the conductive polymer coated region. The relatively bigger white squares located on the left and right sides of the pattern, each 10 mm×10 mm, were dedicated as connections, e.g., to alligator-clips, and are referenced below as ‘connection areas’. The white connection strip between the connection areas (˜2 mm×30−10 mm, varied length) contained a defined amount of material that was measured to determine its resistance. Five different resistors were prepared, varying only in their length but not in their thickness or width (˜350 nm high PEDOT-PSS coating, 2 mm width). The resistors had lengths of 30, 25, 20, 15, and 10 mm.

II. The resistance between the contact areas was measured using a Metex multimeter at room temperature under atmospheric conditions. The measured resistance values, which are rounded for convenience, are shown in Table 20.

III. Those skilled in the art will appreciate that other substrates, e.g., Weyerhaeuser paper, Schott glass slides, and other conducting or semi-conducting materials, e.g., metal, ITO, or polypyrrole, can be used in this process.

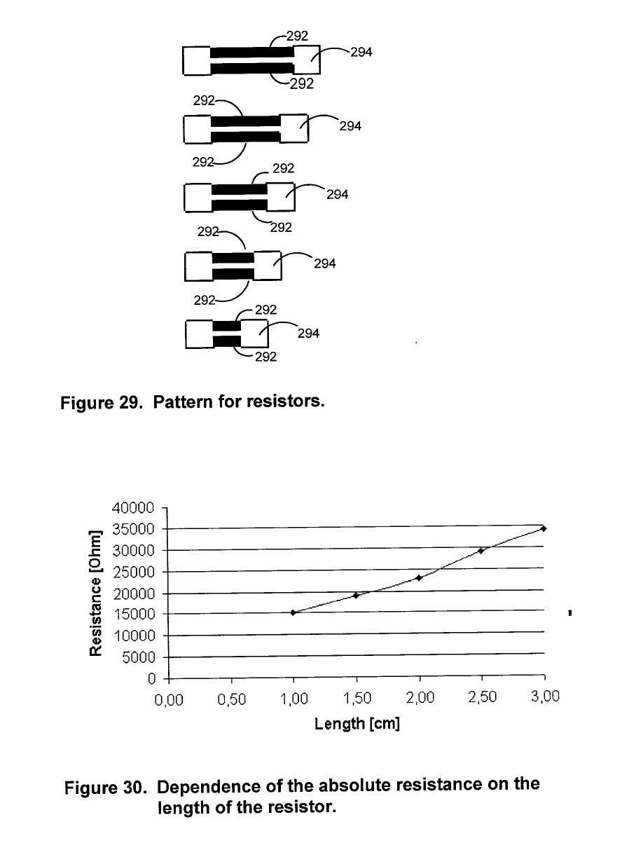

Referring to FIG. 30, a plot 300 of the measured resistance versus the length of the resistor is shown.

TABLE 20
Measurement of resistance as function of the length of the resistive
material.

| Length [cm] | Resistance [Ohms] |
|---|---|
| 1.00 | 15000 |
| 1.50 | 19000 |
| 2.00 | 23000 |
| 2.50 | 29000 |
| 3.00 | 34000 |

### EXAMPLE 29

### Preparation of Capacitor-like Devices with a Well-defined Capacitance

I. Two independent but overlapping areas of PEDOT-PSS, prepared using the Line Patterning process described above (˜350 nm thick), as shown in FIG. 31, were insulated by a ˜0.1 mm thick transparency substrate (Nashua XF-20, Nashua Corp. N.H.). PEDOT-PSS (Composition BED1) was used in a process similar to the one described in Example 1A and a Nashua XF-20 overhead transparency as a substrate. Both sides of the substrate were used for this device.

II. The conductive areas were connected using alligator clips, to a Metex multi-meter in capacitance measurement mode. The total capacitance of the overlapping area of the device was then measured. The area of the device, which was measured using a ruler, was repeatedly decreased by the reduction of the width in increments of 1.50 cm, and the measurements were repeated on each resulting device. The measured values of capacitance are shown in Table 21.

III. Those skilled in the art will appreciate that other substrates, e.g., Weyerhaeuser paper, Schott glass slides, and other conducting or semi-conducting materials, e.g., metal, ITO, or polypyrrole, can be used in this process. Furthermore, multiple substrates can be stacked and electrically connected to obtain higher capacitance, where the capacitance is between two substrates or between both sides of one substrate.

In FIG. 31A, a plot of the capacitance versus the area of the device is shown. In FIG. 31B, overlapping areas corresponding to FIG. 31A is also shown. A connection “A” 314A is connected to an upper conducting polymer 312. Likewise, a connection “B” 314 is connected to a lower conducting polymer 312A. A transparency 316 is disposed between the connections 314 and 314A.

TABLE 21
Measurement of capacitance as function of the
size of the overlapping area

| Length [cm] | Width [cm] | Area [cm²] | Capacity [nF] |
|---|---|---|---|
| 8.00 | 6.50 | 52 | 1.50 |
| 8.00 | 5.00 | 40 | 1.20 |
| 8.00 | 3.00 | 24 | 0.77 |
| 8.00 | 1.50 | 12 | 0.35 |

### EXAMPLE 30

### Field Effect Transistor-like Device

Preparation of a device, possessing properties that are similar to those of a commercial “field effect transistor” device is described with respect to Examples 30 and 31. In the following description, such a device was conveniently referred to as (the) FET-like device. Commonly used terms and expressions, for describing a commercial “FET” and its characteristics, are used for ease of description.

I. Referring to FIG. 32, two patterns of PEDOT-PSS were prepared on transparency film (Nashua XF-20, Nashua Corp., N.H.) using PEDOT-PSS (Composition BED1) in a process similar to the one described in Example 1A and a Nashua XF-20 overhead transparency as a substrate. In FIG. 32, black areas 320 represent the insulating bare substrate, after the removal of the printed lines using the methodology described in Example 4, step VIb (sonication in toluene). The white areas 322 represent the part of the device coated with PEDOT-PSS.

II. Referring to FIG. 35, an operational device corresponding to FIGS. 32A and 32B is shown. Two electrodes 350 were aligned, conducting sides opposing each other. An overlapping area 352 was also formed so that part of the gate area overlapped the active area of the source-drain connection, as shown in FIG. 35 (overlap ˜3 mm×0.5 mm). To obtain a thin insulating layer between the gate and the active area, the following alternatives were determined to be acceptable:

a) Silicon oil (Fisher Scientific) was deposited on the active area of the source-drain connection before placement and alignment of the gate electrode. The silicon oil was empirical observed to spread evenly between both overlapping areas.

b) Acrylic ester or ‘Optical Adhesive NOA-65’ (Norland Products, N.J.), with the help of UV-light, was used as a spacer after polymerization.

c) Commercial candle-wax was placed as a solid grain between both electrodes and was then melted in an oven at approximately 100° C. When the wax was completely spread, the device was removed from the oven to permit solidification of the wax, resulting a solid wax spacer between the electrodes.

d) Silicone elastomer combined with a polymerizing reagent provided a thin insulating layer between the gate and the active area.

e) Epoxy (‘Devcon 5 minute epoxy’) applied between in the electrodes and allowed to cure as a thin layer provided a thin insulating layer between the gate and the active area, of the source drain electrode.

To all of the insulating spacer materials a small amount of glass or plastic spacers (Spacer P-86, E.H.C Co. LTD, Hino Hino-Shi Tokyo, Japan) of different sizes, e.g. 15 μm or 8.6 μm, were added, when appropriate, to keep both electrodes at a well defined distance.

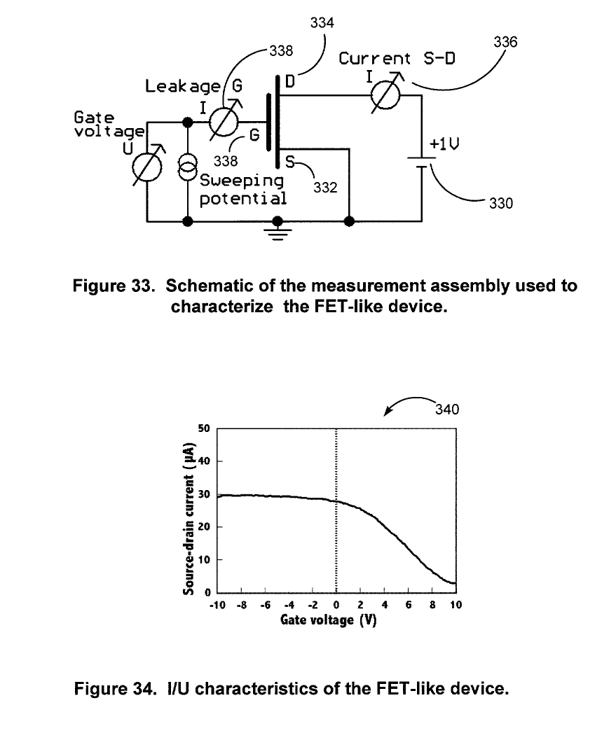

III. Referring to FIG. 33, a schematic of a measurement assembly is shown. After assembly, the device was connected to a constant voltage source 330 (fixed potential of ˜1 Volt) between source (S) 332 and drain (D) 334. An ammeter 336 was used to measure the current through the source and drain(‘Current S-D’) as function of a variable voltage (‘sweeping potential’) connected to the gate (G) 338 (‘Gate voltage’). An additional ammeter 338 was connected between the sweeping voltage source and the gate to detect possible leakage between gate and source-drain (‘Leakage G’). A leakage was assumed to be present when the current flow into the gate exceeded 0.1 μA (e.g., <˜1% of the current flow between source and drain).

IV. Referring to FIG. 34, a plot 340 of current versus voltage is shown obtained by sweeping or varying the voltage through +10 V to −10 V and vice versa at a scan rate of 1 mV/s. At gate voltages greater than ˜10 volt, no change in the current flow through source-drain was observed. Below a gate voltage of, e.g, ˜−2 V, the current between the source and drain again became stable. In the region between a gate voltage of ˜+2 volt and ˜+8 volt, a nearly linear relation between the gate voltage and the source-drain current was observed. This non-Ohmic phenomenon was ascribed to the field-effect-like behaviour of the device. The characteristics matched the characteristics of a p-type material FET.

V. It was determined that similar devices also operated at high voltages, e.g., a gate voltage of ˜+200 V depending on the thickness and kind of insulating layer employed. Furthermore, it was determined that in the cases involving liquid insulators, e.g., silicon oil, the gate could be moved with respect to the source-drain, without interfering with its basic characteristics, which resulted in a very flexible device. Alternatively, pressure could be applied to the overlapping areas to provide a pressure sensitive device.

VI. An operational device is shown in FIG. 35. Those skilled in the art will appreciate that similar “FET”-like devices can be fabricated by using the following:

Different substrates, e.g. transparency film, fabric, paper, ceramics, glass, and the like;

Different organic semiconducting materials, e.g. polyaniline, polypyrrole, polythiophene, pentacene, fullerene and their derivatives, and inorganic semiconductors, e.g. silicon, both in doped and non-doped forms, or composites of all of the above with semiconducting or conducting materials, and the like;

Different insulating materials, e.g. polyethylene, siliconnitride, siliconoxide, air, inert gasses, inert liquids;

Other materials as “insulating” layer, e.g. liquid crystal materials, photo-responsive, radiation-sensitive, thermo-responsive or chemically responsive materials for applications as sensors;

Different spacers, e.g. fibers, mesh, fabric, air, printed lines; and

organic or inorganic conductors, e.g. metal.

### EXAMPLE 31

### Comparative Field Effect Transistor-like Device

I. A commercially available copper wire, coated with an insulator, was cut into a 5 cm long piece. By carefully scratching with a razor blade, the insulating varnish was removed on one end, to provide electrical contact to the wire. This partially insulated length of wire will be referred to as a ‘gate’.

II. A solution of an emeraldine base (EB) in N-methyl-pyrrolidone (NMP), 0.5% by weight, was prepared by dissolving EB in NMP, sonicating for 1 hour, and subsequently filtering the resultant solution. Using a pipette, several drops of this solution of EB in NMP were deposited on the insulated part of the gate. The excess solvent was allowed to evaporate by letting the gate stand in air. The process was repeated until a clearly visible and uniform coating of EB was apparent.

III. The device was placed in a 100° C. oven for 1 hour to allow the remaining solvent to evaporate. The EB was then doped by exposure to concentrated hydrochloric acid vapor for 1 hour.

IV. Two silver wires were placed on the left and right edge of the EB-coating and were fixed and electrically connected to the EB-coating by conductive silver paint. 10 These wires will be referred to as source (S) and drain (D) herein. The silver paste was allowed to solidify in an oven set at 100° C. In FIG. 36, a photograph 360 of the operational device and its schematic representation is shown.

V. The device was connected and characterised in a similar manner to that described in Example 30, Sections III, IV, and V above, resulting in highly similar characteristics to those shown in FIG. 34, although the range of the gate voltage was approximately 200-300 V and the change in S-D current was smaller than the “FET”-like device measured above.

Those skilled in the art will appreciate that similar “FET”-like devices can be fabricated using the following:

Different gate materials, e.g. carbon black, PEDOT, electronic polymer wire and the like;

Different substrates, e.g. transparency film, fabric, paper, ceramics, glass, and the like;

Different organic semiconducting materials, e.g. polyaniline, polypyrrole, polythiophene, pentacene, fullerene and their derivatives, and inorganic semiconductors, e.g. silicon, both in doped and non-doped forms, or composites of all of the above with semiconducting or conducting materials, and the like;

Different insulating materials, e.g. polyethylene, siliconnitride, siliconoxide, air, inert gasses, inert liquids;

Other materials as “insulating” layer, e.g. liquid crystal materials, photo-responsive, radiation-sensitive, thermo-responsive or chemically responsive materials for applications as sensors;

Different spacers, e.g. fibers, mesh, fabric, air, printed lines; and

Organic or inorganic conductors, e.g. metal.

Incorporation by Reference

The entire contents of all patents, published patent applications and other references cited herein are hereby expressly incorporated herein in their entireties by reference.

Equivalents

Those skilled in the art will recognize, or be able to ascertain, using no more than routine experimentation, many equivalents to specific embodiments of the invention described specifically herein. Such equivalents are intended to be encompassed in the scope of the following claims.

What is claimed:

1. A method of forming a pattern of a functional material on a substrate comprising:
applying a first pattern of a first material to said substrate; and
applying a second functional material to said substrate and said first material, wherein said first material, said second functional material, and said substrate interact to spontaneously form a second pattern of said second functional material on said substrate, to thereby form a pattern of a functional material a substrate.

2. The method of claim 1, further comprising applying an additional pattern of an additional material to said substrate, to thereby form a multi-layered pattern of materials on said substrate.

3. The method of claim 2, wherein said additional material is the same as said first material.

4. The method of claim 2, wherein said additional material is the same as said second material.

5. The method of claim 2, wherein said additional material is different from said first and second materials.

6. The method of claim 2, wherein said additional pattern is different from said first pattern.

7. The method of claim 2, wherein said additional pattern is different from said second pattern.

8. The method of claim 3, wherein said additional pattern is orthogonal to said first pattern.

9. The method of claim 8, wherein said additional pattern is a chessboard pattern.

10. The method of claim 5, wherein said additional pattern of additional material overlays said first and second patterns, thereby creating a multi-layer composite material.

11. The method of claim 10, wherein said first and second materials are electrically conducting materials, thereby creating electrically conducting junctions.

12. The method of claim 1, wherein said second material is applied substantially uniformly to said substrate containing said first pattern.

13. The method of claim 1, wherein said second material comprises an information carrying material such that said second pattern possesses engineered functionality.

14. The method of claim 1, wherein said interaction among said first material, said second material, and said substrate is selected from the group of interactions consisting of hydrophobic/hydrophilic, solvent wettablility, ionic forces, ion-dipole forces, hydrogen bonds, charge transfer forces, Van der Waals forces, chemical (covalent) bonds, general mechanical adhesion, penetration, and magnetic interactions.

15. The method of claim 14, wherein said interaction among said first material, said second material, and said substrate is hydrophobic/hydrophilic.

16. The method of claim 1, further comprising removing said first pattern of the first material from said substrate.

17. The method of claim 1, wherein said first pattern of the first material is applied by a method selected from the group consisting of non-contact printing, photolithographic printing, offset printing, silk-screen printing, stamping, etching, hand-drawing, and any combination thereof.

18. The method of claim 17, wherein said first pattern of the first material is applied by non-contact printing.

19. The method of claim 18, wherein said non-contact printing comprises electrophotographic printing.

20. The method of claim 18, wherein said first pattern of the first material is applied by laser printing.

21. The method of claim 18, wherein said first pattern of the first material is applied by xerographic printing.

22. The method of claim 18, wherein said first pattern of the first material is applied by solid ink printing.

23. The method of claims 20 or 21, wherein said first material comprises a toner ink.

24. The method of claim 18, wherein said first pattern of the first material has a line resolution of at least about 10 μm.

25. The method of claim 1, wherein said second pattern is the same as said first pattern.

26. The method of claim 1, wherein said second pattern is the inverse of said first pattern.

27. The method of claim 1, wherein said substrate is selected from the group consisting of glass, metal, plastic, wood, fabric, paper, quartz, crystal, stone, and ceramic.

28. A method of forming a pattern of a functional material on a substrate comprising:
non-contact printing a first pattern of a first material on said substrate; and
applying a second functional material to said substrate and said first material, wherein said first material, said second material, and said substrate interact to spontaneously form a second pattern of said second functional material on said substrate, to thereby form a pattern of a functional material on a substrate.

29. The method of claim 28, wherein said interactions between said first material, said second material, and said substrate are hydrophobic/hydrophilic such that said first material, said second material, and said substrate interact to spontaneously form a second pattern of said second material on said substrate.

30. The method of claim 28, further comprising removing said first pattern of the first material from said substrate.

31. The method of claim 28, wherein said non-contact printing comprises electrophotographic printing.

32. The method of claim 28, wherein said first pattern of the first material is applied by laser printing.

33. The method of claim 28, wherein said first pattern of the first material is applied by xerographic printing.

34. The method of claim 28, wherein said first pattern of the first material is applied by solid ink printing.

35. The method of claims 32 or 33, wherein said first material comprises a toner ink.

36. The method of claim 28, wherein said first pattern of the first material has a line resolution of at least about 10 μm.

37. The method of claim 28, wherein said second pattern is the inverse of said first pattern.

38. The method of claim 28, wherein said substrate is flexible.

39. The method of claim 28, wherein said flexible substrate is selected from the group consisting of paper, plastic, and fabric substrates.

40. The method of claim 28, wherein said second material comprises an electrically active material.

41. The method of claim 40, wherein said second material comprises an electrically conductive polymer.

42. The method of claim 41, wherein said second material comprises an aqueous mixture of an electrically conductive polymer.

43. The method of claim 28, wherein said first material has an electrical conductance that is lower than that of said second material.

44. The method of claim 28, wherein said first material is electrically nonconductive ink.

45. The method of claim 28, wherein said substrate has an electrical conductance that is lower than that of said second material.

46. The method of claim 28, wherein said second material is electrically non-conductive.

47. A method of forming a pattern of a functional material on a substrate comprising:
non-contact printing a first pattern of a first material on said substrate; and
applying a second functional material to said substrate and said first material, wherein said first and second functional materials are selected to have a sufficient difference in at least one property of hydrophobicity and hydrophilicity relative to one another such that said first material, said second functional material, and said substrate interact to spontaneously form a second pattern of said second functional material on said substrate, to thereby form on said substrate a second pattern of said second functional material, wherein said second pattern is the inverse of said first pattern, to thereby form a pattern of a functional material to a substrate.

48. The method of claim 47, further comprising removing said first pattern of the first material from said substrate.

49. The method of claim 47, wherein said non-contact printing comprises electrophotographic printing.

50. The method of claim 47, wherein said non-contact printing comprises laser printing.

51. The method of claim 47, wherein said non-contact printing comprises xerographic printing.

52. The method of claim 47, wherein said first pattern of the first material is applied by solid ink printing.

53. The method of claim 47, wherein said substrate is flexible.

54. The method of claims 50 or 51, wherein said first material comprises a toner ink.

55. The method of claim 54, wherein said second material comprises an aqueous solution of an electrically conductive polymer.

56. The method of claim 55, wherein said substrate and said toner ink are electrically non-conducting relative to said electrically conductive polymer.

57. A method of forming an electrical circuit element, comprising:
applying a first pattern of a first material on a substrate; and
applying a second material to said substrate and said first material, wherein said first material, said second material, and said substrate interact to spontaneously form a second pattern of said second material on said substrate, thereby forming an electrical circuit element.

58. The method of claim 57, wherein said first pattern of the first material is applied by non-contact printing.

59. The method of claim 57, wherein said non-contact printing comprises electrophotographic printing.

60. The method of claim 58, wherein said non-contact printing comprises laser printing.

61. The method of claim 58, wherein said non-contact printing comprises xerographic printing.

62. The method of claim 58, wherein said solid ink printing.

63. The method of claims 60 or 61, wherein said first material comprises a toner ink.

64. The method of claim 58, wherein said first pattern of the first material has a line resolution of at least about 10 μm.

65. The method of claim 57, wherein said second pattern is the inverse of said first pattern.

66. The method of claim 57, wherein said substrate is selected from the group consisting of glass, metal, plastic, wood, fabric, paper, quartz, crystal, stone, and ceramic.

67. The method of claim 57, wherein said first and second materials are selected to have a sufficient difference in at least one property of hydrophobicity and hydrophilicity relative to one another such that said first material, said second material, and said substrate interact to spontaneously form a second pattern of said second material on said substrate.

68. The method of claim 57, further comprising removing said first pattern of said first material.

69. The method of claim 67, wherein said substrate is a flexible substrate.

70. The method of claim 67, wherein said substrate is a flexible plastic substrate.

71. The method of claim 70, wherein said first material is electrically non-conductive.

72. The method of claim 71, wherein said first material is a toner ink.

73. The method of claim 67, wherein said first material is a polyimide.

74. The method of claim 72, wherein said second material is an electrically active material.

75. The method of claim 74, wherein said electrically active material is an electrically conductive material that is selected from the group consisting of polymeric material, a metallic dispersion, a metallic solution, a sol gel of indium tin oxide, a non-polymeric material, and a derivative thereof.

76. The method of claim 75, wherein said polymeric material is selected from the group consisting of a polypyrrole, a polythiophene, a polyaniline, a poly-phenylenevinylene, and a polyacetylene, and a derivative thereof.

77. The method of claim 76, wherein said polymer comprises poly-3,4-ethylenedioxythiophene-polystyrene sulfonate (PEDOT-PSS).

78. The method of claim 74, wherein said electrically conductive material comprises a non-polymer selected from the group consisting of a phthalocyanine, a porphyrin, an anthracene, a fullerene, a triphenylamine, a stilbene, and a derivative thereof.

79. The method of claim 57, wherein said second material is applied substantially uniformly to said substrate containing said first pattern.

80. The method of claim 79, wherein said second material is applied by rolling the second material onto the substrate, spraying the second material onto the substrate, melting the second material onto the substrate, dipping the substrate into the second material, or exposing the substrate to gasses or vapors of the second material.

81. The method of claim 79, further comprising applying a third material by rolling the third material onto the substrate, spraying the third material onto the substrate, melting the third material onto the substrate, dipping the substrate into the third material, or exposing the substrate to gasses or vapors of the third material, wherein the combination of the second and third material produces a functionally active fourth material.

82. The method of claim 68, wherein said first material is removed by ultrasonic treatment with a solvent, cleaning with a solvent, cleaning by mechanical action, adhesive modification through chemical alteration, evaporation or melting.

83. The method of claim 57, wherein said circuit element is selected from the group consisting of an inductor, a resistor, a capacitor, an Inductor-Capacitor (LC) resonator, a switch, a filter, a transistor, a Schottky junction, a p-n junction, and a sensor.

84. The method of claim 57, wherein said circuit element is an inductor.

85. The method of claim 57, wherein said circuit element is a resistor.

86. The method of claim 57, wherein said circuit element is a capacitor.

87. The method of claim 57, wherein said circuit element is an Inductor-Capacitor (LC) resonator.

88. The method of claim 57, wherein said circuit element is a switch.

89. The method of claim 57, wherein said circuit element is a filter.

90. The method of claim 57, wherein said circuit element is a transistor.

91. The method of claim 57, wherein said circuit element is a Schottky junction.

92. The method of claim 57, wherein said circuit element is a p-n junction.

93. The method of claim 57, wherein said circuit element is a sensor.

94. The method of claim 57, wherein said circuit element is an electric stress sensor.

95. The method of claim 83, wherein said circuit element comprises a n inductor and said second pattern comprises at least one of a serpentine pattern and a spiral pattern.

96. The method of claim 83, wherein said circuit element comprises a resistor defined by the length, width, and height of said second pattern and the conductivity of said second material.

97. The method of claim 83, wherein said circuit element comprises a capacitor, wherein the first material is a dielectric and the second material is an electrically conductive material that further comprises an interdigitated pattern of said first and said second materials on said substrate to thereby form a pattern of said electrically conductive second material on said substrate separated by a dielectric.

98. The method of claim 97, further comprising removing said first pattern of first material from said substrate, thereby providing a capacitor comprised of a pattern of said electrically conductive second material on said substrate, wherein air is said dielectric.

99. The method of claim 83, wherein said circuit element comprises a capacitor, wherein said pattern of said first material is applied to both sides of said substrate and said second material is applied to said patterns of said first material on said substrate, wherein said second pattern forms on both sides of said substrate, such that said second material is electrically conductive and said second patterns overlap, at least in part, to thereby form two patterns of said electrically conductive second material on said substrate separated by said dielectric substrate.

100. The method of claim 83, wherein said circuit element further comprises a second circuit element, wherein said second circuit element is formed by: non-contact printing a third pattern of a third material on a second substrate; and applying a fourth material to said second substrate and said third material; wherein said third material, said fourth material, and said substrate interact to spontaneously form a second pattern of said fourth material on said substrate, wherein the second material and fourth material on said first and said second substrates comprise an electrically conductive material, and said pattern of said first substrate and said pattern of said second substrate are opposed to each other so as to form a switch in which the electrically conductive material on each substrate is separated by the respective heights on the substrates of the first material and the third material until at least one of the substrates is depressed so as to put the electrically conductive materials into electrical contact with each other.

101. The method of claim 100, wherein said first and third materials are the same.

102. The method of claim 83, wherein said filter is a Resistor-Capacitor (RC) filter.

103. The method of claim 90, wherein said filter comprises a first pattern of electrically conductive material connected to electrical ground and a second pattern of electrically conductive material connected to an input signal at one end of said second pattern and to an output at another end of said second pattern, said circuit further comprising at least one capacitor electrically connected between said first and second patterns to form an RC filter.

104. The method of claim 83, wherein said transistor is a field effect transistor-like device.

105. The method of claim 104, wherein said electrically conductive material comprises a semi-conducting polymer material deposited on said substrate as at least one of a source, a drain, and a connection between said source and drain.

106. The method of claim 105, further comprising applying said semi-conducting polymer material as a control layer forming a gate disposed over said electrically conductive polymer material connecting said source and said drain and separated therefrom by an insulator.

107. The method of claim 105, wherein said semi-conducting polymer material is selected from the group consisting of a phthalocyanine, a porphyrin, an anthracene, a fullerene, a triphenylamine, a stilbene, and a derivative thereof.

108. The method of claim 72, further comprising removing said first pattern of toner ink by ultrasound treatment with an organic solvent.

109. An electrical circuit element prepared by the method of any one of claims 57, 67, or 68.

110. An electrical circuit element comprising:
a substrate;
a first pattern of an insulating material applied to said substrate; and
a second pattern of an electrically conducting material applied to said substrate and said first material, wherein said insulating material, electrically conducting material, and said substrate interact to spontaneously form a second pattern of said electrically conducting material on said substrate when said electrically conducting material is applied to said substrate having said first pattern of said insulating material applied thereon.

111. The electrical circuit element of claim 110, wherein said first pattern of the first material is applied by a method selected from the group consisting of non-contact printing, photolithographic printing, offset printing, silk-screen printing, stamping, etching, hand-drawing, and any combination thereof.

112. The electrical circuit element of claim 111, wherein said first pattern of the first material is applied by non-contact printing.

113. The electrical circuit element of claim 111, wherein said non-contact printing comprises electrophotographic printing.

114. The electrical circuit element of claim 112, wherein said non-contact printing comprises laser printing.

115. The electrical circuit element of claim 112, wherein non-contact printing comprises xerographic printing.

116. The electrical circuit element of claim 112, wherein said first pattern of the first material is applied by solid ink printing.

117. The electrical circuit element of claims 114 or 115, wherein said first material comprises a toner ink.

118. The electrical circuit element of claim 112, wherein said first pattern of the first material has a line resolution of at least about 10 μm.

119. The electrical circuit element of claim 110, wherein said substrate is selected from the group consisting of glass, metal, plastic, wood, fabric, paper, quartz, crystal, stone, and ceramic.

120. The electrical circuit element of claim 110, wherein said first pattern is removed from said substrate.

121. The electrical circuit element of claim 110, wherein said electrically conducting material comprises poly-3,4-ethylenedioxythiophene-polystyrene sulfonate (PEDOT-PSS).

122. The electrical circuit element of claim 110, wherein said second pattern is the inverse of said first pattern.

123. An electronic device comprising:
a) a first circuit element comprising
i) a first substrate;
ii) a first pattern of an insulating material applied to said substrate and
iii) a second pattern of an electrically conducting material applied to said substrate and said first material, wherein said insulating material, electrically conducting material, and said substrate interact to spontaneously form a second pattern of said electrically conducting material on said substrate when said electrically conducting material is applied to said substrate having said first pattern of said insulating material applied thereon;
b) a second circuit element comprising
i) a second substrate;
ii) a third pattern of an insulating material applied to said second substrate and
iii) a fourth pattern of an electrically conducting material applied to said second substrate and said third material, wherein said insulating material, electrically conducting material, and said second substrate interact to spontaneously form a fourth pattern of said electrically conducting material on said substrate when said electrically conducting material is applied to said substrate having said third pattern of said insulating material applied thereon; and
c) an electrical connection between said first and second circuit elements.

124. The electronic device of claim 123, wherein said electrical connection is provided by a fastener selected from the group consisting of a rivet, a grommet, a metal staple, a coated metal staple, a metal wire, a snap, and a coated metal wire.

125. The electronic device of claim 124, wherein said electrical connection is a grommet.

126. The electronic device of claim 124, wherein said electrical connection is a metal wire.

127. A Radio Frequency (RF) tag comprising a pattern of a nonconductive first material on a substrate and a coating of an electrically conductive second material disposed over said substrate and said first material, wherein said first material, said second material, and said substrate interact to spontaneously form a second pattern of said second material on said substrate, to thereby form an Inductor-Capacitor (LC) resonator on said substrate.

128. The RF tag of claim 127, wherein said first pattern of the first material is applied by a method selected from the group consisting of non-contact printing, photolithographic printing, offset printing, silk-screen printing, stamping, etching, hand-drawing, and any combination thereof.

129. The RF tag of claim 128, wherein said first pattern of the first material is applied by non-contact printing.

130. The RF tag of claim 128, wherein said non-contact printing comprises electrophotographic printing.

131. The RF tag of claim 128, wherein non-contact printing comprises laser printing.

132. The RF tag of claim 128, wherein non-contact printing comprises xerographic printing.

133. The RF tag of claim 128, wherein said first pattern of the first material is applied by solid ink printing.

134. The RF tag of claims 131 or 132, wherein said first material comprises a toner ink.

135. The RF tag of claim 128, wherein said first pattern of the first material has a line resolution of at least about 10 μm.

136. The RF tag of claim 127, wherein said second pattern is the inverse of said first pattern.

137. The RF tag of claim 127, wherein said substrate is selected from the group consisting of glass, metal, plastic, wood, fabric, paper, quartz, crystal, stone, and ceramic.

138. The RF tag of claim 127, wherein said electrically conductive material and said pattern of said first material together form a capacitor and an inductor on a same side of said substrate.

139. The RF tag of claim 127, wherein said electrically conductive material and said pattern of said first material together form a capacitor and an inductor on respective sides of said substrate that are connected to one another through the substrate.

140. The RF tag of claim 127, wherein said first material and said substrate being selected to have sufficient differences in at least one of hydrophobicity and hydrophilicity relative to said electrically conductive second material.

141. An mechanical device comprising:
a) a first component comprising
i) a first substrate;
ii) a first pattern of first material applied to said first substrate and
iii) a second pattern of material applied to said first substrate and said first material, wherein said second pattern of said second material is spontaneously formed by the interaction of said first material, said second material and said first substrate; and
b) a second component comprising
i) a second substrate;
ii) a third pattern of a third material applied to said second substrate and
iii) a fourth pattern of fourth material applied to said second substrate and said third material, wherein said fourth pattern of said fourth material is spontaneously formed by the interaction of said third material, said fourth material and said substrate; and
wherein said first and second components are oriented in a such a way that the second and fourth patterns oppose each other, and are selected from the group consisting of identical patterns, inverse patterns, and any mechanically useful combinations.

142. The mechanical device of claim 141, wherein said first and third patterns of said first and third materials are applied by a method selected from the group consisting of non-contact printing, photolithographic printing, offset printing, silk-screen printing, stamping, etching said substrate with ink, hand-drawing, and any combination thereof.

143. The mechanical device of claim 142, wherein said first and third patterns of said first and third materials are applied by non-contact printing.

144. The mechanical device of claim 142, wherein said non-contact printing comprises electrophotographic printing.

145. The mechanical device of claim 143, wherein said non-contact printing comprises laser printing.

146. The mechanical device of claim 143, wherein said non-contact printing comprises xerographic printing.

147. The mechanical device of claim 143, wherein said non-contact printing comprises solid ink printing.

148. The mechanical device of claims 145 or 146, wherein said first and third materials comprise a toner ink.

149. The mechanical device of claim 143, wherein the first and third patterns of the first and third materials have a line resolution of at least about 10 μm.

150. The mechanical device of claim 141, wherein said first and second substrates are selected from the group consisting of glass, metal, plastic, wood, fabric, paper, quartz, crystal, stone, and ceramic.

151. The mechanical device of claim 141 selected from the group consisting of a micro-fluidic channel, a seal, a snap-in fittings, a keypad, and a touch-pad.

152. The mechanical device of claim 151 comprising a micro-fluidic channel.

153. The mechanical device of claim 151 comprising a seal.

154. The mechanical device of claim 151 comprising a snap-in fitting.

155. The mechanical device of claim 151 comprising a touch-pad.

156. The mechanical device of claim 151 comprising a keypad.

157. A mechanical device prepared by the method of any one of claims 1, 28 or 47.
